(19) United States
(12) Patent Application Publication
(10) Pub. No.: US 2010/0327452 A1
(43) Pub. Date: Dec. 30, 2010

(54) MOUNTING STRUCTURE AND METHOD OF MANUFACTURING THE SAME

(76) Inventor: Hirotsugu Kobayashi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 12/735,820

(22) PCT Filed: Feb. 24, 2009
(86) PCT No.: PCT/JP2009/053277

§ 371 Date: Aug. 19, 2010

(30) Foreign Application Priority Data
Mar. 5, 2008 (JP) 2008-055640
Aug. 12, 2008 (JP) 2008-208262

(51) Int. Cl. H01L 23/48; H01L 21/50

(52) U.S. Cl. 257/773; 438/106; 257/E21.499; 257/E23.01

(57) ABSTRACT

To provide a mounting structure having a substrate and a semiconductor package mounted thereon which enables suppression of unnecessary electromagnetic radiation and improvement of drop impact resistance, and a method of manufacturing the same. A substrate 1 includes, formed on the surface thereof, multiple electrode pads 12 for mounting a semiconductor package thereon and multiple electrode pads 13 electrically connected to a power/ground layer 17. A conductive wire 31 mechanically and electrically connected to the electrode pad 13 with at least two points is placed above the surface of the substrate 1 to improve the stiffness of the surface of the substrate 1. A semiconductor package 4 is mechanically and electrically connected to the surface of the substrate 1 by the electrode pad 12. The suppression of unnecessary electromagnetic radiation generated from a transmission signal and improvement of drop impact resistance are achieved by the conductive wire 31.

### TECHNICAL FIELD

The present invention relates to a mounting structure and a method of manufacturing the same and, more particularly, to a mounting structure that includes a substrate and a semiconductor package mounted thereon and achieves both suppression of unnecessary electromagnetic radiation and improvement of drop impact resistance, and a method of manufacturing the same.

### BACKGROUND ART

Along with the recent advancement in technologies, electronic instruments have been miniaturized and densified, and speedup of the transmission signal has advanced. The performance of semiconductors to be used has been improved rapidly. A clock frequency ranging from 3 to 5 GHz within a semiconductor chip has been put into practical use. It is expected that a clock frequency of 10 GHz or more is achieved in the future. It is also expected that a transmission signal from a semiconductor chip to a substrate has a frequency as high as 1.8 GHz to 4 GHz.

Along with the speedup of the transmission signal, the electromagnetic radiation which is unnecessary for the signal transmission is liable to occur. It is well known that the main cause of the unnecessary electromagnetic radiation resides in a non-conductor area (hereinafter referred to as “clearance”) that is formed around via holes of a ground layer or a power supply layer in a wiring board. In consideration of this point, measures to form a pathway to make up for the clearance and to reduce the size of the clearance have been taken. Moreover, in a printed wiring board, unnecessary electromagnetic radiation from the transmission signal is inhibited by adopting a stripline and a microstrip-line.

For example, in a printed wiring board described in FIG. 1 of Japanese Unexamined Patent Application Publication No. 2004-22140 (Patent Document 1), radiation noise or crosstalk noise of a high-performance digital signal is inhibited by devising a layout of a guard ground wirings formed therein, thereby achieving wiring with a desired density.

On the other hand, semiconductor packages are applied to various electronic devices. In the semiconductor packages, it is necessary to secure the reliability of the drop impact resistance or the like. Particularly, in the semiconductor packages used in portable electronic devices, the necessity is high. Therefore, structures that satisfy the demand have been conventionally proposed.

For example, in the mounting structure described in FIG. 1 of Japanese Unexamined Patent Application Publication No. 11-163049 (Patent Document 2), BGAs (Ball Grid Arrays) consisting of solder balls are formed in the back surface of a semiconductor package as outside electrodes. After implementation of the semiconductor package in the surface of the substrate using those solder balls, an underfill resin is injected in a gap between the semiconductor package and the substrate. This allows the underfill resin to enter an area from the four corners of the projection area of the semiconductor package to a location slightly inside the four corners. Then, in the state, the underfill resin is cured by heating, thereby securing a desired drop impact resistance.

### DISCLOSURE OF INVENTION

### Patent Document 1

Japanese Unexamined Patent Application Publication No. 2004-22140 (Page 11, FIG. 1)

### Patent Document 2

Japanese Unexamined Patent Application Publication No. 11-163049 (Page 4, FIG. 1)

### TECHNICAL PROBLEM

In the printed wiring board disclosed in Japanese Unexamined Patent Application Publication No. 2004-22140 (Patent Document 1), unnecessary electromagnetic radiation from the transmission signal is suppressed. However, it is limited to the inside of the printed wiring board. As the density of the signal transmission pathway in the component becomes higher in the future, the guidance of the pathway to drain the return current of a current flowing through signal wiring (a signal pattern) near the signal wiring becomes difficult. Therefore, it becomes difficult to suppress unnecessary electromagnetic radiation merely by components such as the printed wiring board (substrate) or the semiconductor package.

In the mounting structure disclosed in Japanese Unexamined Patent Application Publication No. 11-163049 (Patent Document 2), in order to improve the drop impact resistance of the mounting structure, it is necessary to inject an underfill resin in the gap between the semiconductor package and the substrate. In this mounting structure, after implementation of the semiconductor package on the substrate, the underfill resin is injected in the gap and is then cured by heating. The drop impact resistance is secured by improving the overall stiffness of the mounting structure. However, a drawback that a rework work cannot be carried out occurs because of the existence of the underfill resin.

Moreover, in this mounting structure, the underfill resin which is a polymer material intervenes between connection materials (solder balls) which connect the substrate to the semiconductor package. This raises a concern that the loss of the transmitted high-frequency signals increases.

The present invention has been made in view of the above-mentioned circumstances, and has an object to provide a mounting structure that can achieve both suppression of unnecessary electromagnetic radiation and improvement of the drop impact resistance in a structure including a semiconductor package mounted on the substrate.

The other object of the invention that is not specified here is clear from the following description and the attached drawings.

### TECHNICAL SOLUTION

(1) A first exemplary aspect of the present invention is a mounting structure having a substrate and a semiconductor package mounted thereon, including: a plurality of first electrode pads forming the surface of the substrate and being provided for mounting the semiconductor package on the surface of the substrate; a plurality of second electrode pads forming the surface of the substrate and being electrically connected to a power supply layer or a ground layer in the substrate; and a first conductive wire being mechanically and electrically connected to the second electrode pads with at least two points above the surface of the substrate. The semiconductor package is mechanically and electrically connected to the surface of the substrate by using the first electrode pads.

The mounting structure according to the first exemplary aspect of the present invention is provided with the first conductive wire that is connected to the second electrode pad, which electrically connects with the power supply layer or the ground layer (hereinafter referred to as “power supply/ground layer”) of the substrate, with at least two points. Therefore, unnecessary electromagnetic radiation occurring from a transmission signal flowing through the signal transmission line in the mounting structure can be suppressed.

In addition, because the first conductive wire, which is mechanically and electrically connected to the second electrode pad with at least two points, exists in the surface of the substrate, the stiffness in the front side of the substrate can be enhanced without injecting an underfill resin between the surface of the semiconductor package and the substrate. Therefore, the drop impact resistance of the mounting structure can be improved.

Note that the substrate need not include any semiconductor package, or may include a semiconductor package (i.e., a package substrate).

(2) In a preferred example of the mounting structure according to the first exemplary aspect of the present invention, the second electrode pads are placed at a location to overlap clearances formed in the power supply layer or the ground layer.

(3) In another preferred example of the mounting structure according to the first exemplary aspect of the present invention, the first conductive wire is covered with an insulating material.

(4) In further another preferred example of the mounting structure according to the first exemplary aspect of the present invention, the first conductive wire is provided in a plural number, and at least one of the first conductive wires is connected to the second electrode pads with at least two points above the surface of the substrate.

(5) In further another preferred example of the mounting structure according to the first exemplary aspect of the present invention, the first conductive wire is provided in a plural number, and at least two of the first conductive wires are arranged in a cross-shape or a lattice shape above the surface of the substrate.

(6) In further another preferred example of the mounting structure according to the first exemplary aspect of the present invention, the substrate is a package substrate comprising a semiconductor package.

(7) In further another preferred example of the mounting structure according to the first exemplary aspect of the present invention, a plurality of third electrode pads, which are electrically connected to the power supply layer or the ground layer in the substrate; and a second conductive wire, which is mechanically and electrically connected to the third electrode pads with at least two points, the third electrode pads and the second conductive wire being formed on the back surface of the substrate.

(8) In further another preferred example of the mounting structure according to the first exemplary aspect of the present invention, at least one package substrate is disposed between the surface of the package substrate and the semiconductor package.

(9) A second exemplary aspect of the present invention is a manufacturing method of a mounting structure having a substrate and a semiconductor package mounted thereon, including the steps of: preparing for a substrate having, formed on the surface thereof, a plurality of first electrode pads to mount a semiconductor package and a plurality of second electrode pads electrically connected in a power supply layer or a ground layer; arranging, above the surface of the substrate, a first conductive wire mechanically and electrically connected to the second electrode pads with at least two points; and mounting a semiconductor package above the surface of the substrate by employing the first electrode pads.

According to the manufacturing method of the mounting structure according to the second exemplary aspect of the present invention, it is apparent that the mounting structure according to the first exemplary aspect of the present invention can be manufactured without largely changing a conventional method because the above-mentioned steps are included.

(10) In a preferred example of the manufacturing method of the mounting structure according to the second exemplary aspect of the present invention, the first conductive wire is provided in a plural number, and a part of the first conductive wire is arranged in a first direction above the surface of the substrate, and then the remainder of the first conductive wire is arranged to be aligned in a second direction above the surface of the substrate, the second direction being different from the first direction.

(11) In further another preferred example of the mounting structure according to the second exemplary aspect of the present invention, the first conductive wire is provided in a plural number, a part of the first conductive wire is aligned in a first direction above the surface of the substrate, and then the remainder of the first conductive wire is aligned in a second direction above the surface of the substrate, the second direction being different from the first direction, and all the first conductive wires are collectively arranged in the surface of the substrate.

(12) In further another preferred example of the mounting structure according to the second exemplary aspect of the present invention, in the step of arranging the first conductive wire above the surface of the substrate, the first conductive wire is mechanically and electrically connected to the second electrode pad using a solder.

(13) In further another preferred example of the mounting structure according to the second exemplary aspect of the present invention, in the step of arranging the first conductive wire above the surface of the substrate, the first conductive wire is mechanically and electrically connected to the second electrode pad by laser welding.

### ADVANTAGEOUS EFFECTS

The mounting structure according to the first exemplary aspect of the present invention has an advantageous effect of achieving both suppression of unnecessary electromagnetic radiation and improvement of the drop impact resistance in a structure implementing a semiconductor package on a substrate.

The manufacturing method of the mounting structure according to the second exemplary aspect of the present invention has an advantageous effect of achieving production of the mounting structure of the first exemplary aspect of the present invention without largely changing a conventional method.

### BRIEF DESCRIPTION OF DRAWINGS

FIG. 1A is a perspective view from the top surface, showing an outline constitution of a mounting structure according to a first exemplary embodiment of the present invention;

FIG. 1B is a partial sectional view taken along the line A-A of FIG. 1A, showing an outline constitution of the mounting structure of the first exemplary embodiment of the present invention;

FIG. 1C is a partial sectional view taken along the line B-B of FIG. 1A, showing an outline constitution of the mounting structure of the first exemplary embodiment of the present invention;

FIG. 2A is a perspective view from the top surface, showing an outline constitution of a mounting structure according to a second exemplary embodiment of the present invention;

FIG. 2B is a partial sectional view taken along the line A-A of FIG. 2A, showing an outline constitution of the mounting structure of the second exemplary embodiment of the present invention;

FIG. 2C is a partial sectional view taken along the line B-B of FIG. 2A, showing an outline constitution of the mounting structure of the second exemplary embodiment of the present invention;

FIG. 3A is a perspective view from the top surface, showing an outline constitution of a mounting structure according to a third exemplary embodiment of the present invention;

FIG. 3B is a partial sectional view taken along the line A-A of FIG. 3A, showing an outline constitution of the mounting structure of the third exemplary embodiment of the present invention;

FIG. 3C is a partial sectional view taken along the line B-B of FIG. 3A, showing an outline constitution of the mounting structure of the third exemplary embodiment of the present invention;

FIG. 4A is a perspective view from the top surface, showing an outline constitution of a mounting structure according to a fourth exemplary embodiment of the present invention;

FIG. 4B is a partial sectional view taken along the line A-A of FIG. 4A, showing an outline constitution of the mounting structure of the fourth exemplary embodiment of the present invention;

FIG. 4C is a partial sectional view taken along the line B-B of FIG. 4A, showing an outline constitution of the mounting structure of the fourth exemplary embodiment of the present invention;

FIG. 5A is a perspective view from the top surface, showing an outline constitution of a mounting structure according to a fifth exemplary embodiment of the present invention;

FIG. 5B is a partial sectional view taken along the line A-A of FIG. 5A, showing an outline constitution of the mounting structure of the fifth exemplary embodiment of the present invention;

FIG. 5C is a partial sectional view taken along the line B-B of FIG. 5A, showing an outline constitution of the mounting structure of the fifth exemplary embodiment of the present invention;

FIG. 6A is a perspective view from the top surface, showing an outline constitution of a mounting structure according to a sixth exemplary embodiment of the present invention;

FIG. 6B is a partial sectional view taken along the line A-A of FIG. 6A, showing an outline constitution of the, mounting structure of the sixth exemplary embodiment of the present invention;

FIG. 6C is a partial sectional view taken along the line B-B of FIG. 6A, showing an outline constitution of the mounting structure of the sixth exemplary embodiment of the present invention;

FIG. 7A is a perspective view from the top surface, showing an outline constitution of a mounting structure according to a seventh exemplary embodiment of the present invention;

FIG. 7B is a partial sectional view taken along the line A-A of FIG. 7A, showing an outline constitution of the mounting structure of the seventh exemplary embodiment of the present invention;

FIG. 7C is a partial sectional view taken along the line B-B of FIG. 7A, showing an outline constitution of the mounting structure of the seventh exemplary embodiment of the present invention;

FIG. 8A is a perspective view from the top surface, showing an outline constitution of a mounting structure according to an eighth exemplary embodiment of the present invention;

FIG. 8B is a partial sectional view taken along the line A-A of FIG. 8A, showing an outline constitution of the mounting structure of the eighth exemplary embodiment of the present invention;

FIG. 8C is a partial sectional view taken along the line B-B of FIG. 8A, showing an outline constitution of the mounting structure of the eighth exemplary embodiment of the present invention;

FIG. 9A is a perspective view from the top surface, showing each step of a manufacturing method of the mounting structure according to a ninth exemplary embodiment of the present invention;

FIG. 9B is a perspective view from the top surface showing each step of the manufacturing method of the mounting structure according to the ninth exemplary embodiment of the present invention;

FIG. 9C is a perspective view from the top surface, showing each step of the manufacturing method of the mounting structure according to the ninth exemplary embodiment of the present invention;

FIG. 9D is a perspective view from the top surface, showing each step of the manufacturing method of the mounting structure according to the ninth exemplary embodiment of the present invention;

FIG. 9E is a perspective view from the top surface, showing each step of the manufacturing method of the mounting structure according to the ninth exemplary embodiment of the present invention;

FIG. 9F is a perspective view from the top surface, showing each step of the manufacturing method of the mounting structure according to the ninth exemplary embodiment of the present invention;

FIG. 9G is a perspective view from the top surface, showing each step of the manufacturing method of the mounting structure according to the ninth exemplary embodiment of the present invention;

FIG. 10A is a perspective view from the top surface, showing each step of a manufacturing method of the mounting structure according to a tenth exemplary embodiment of the present invention;

FIG. 10B is a perspective view from the top surface, showing each step of the manufacturing method of the mounting structure according to the tenth exemplary embodiment of the present invention;

FIG. 10C is a perspective view from the top surface, showing each step of the manufacturing method of the mounting structure according to the tenth exemplary embodiment of the present invention;

FIG. 10D is a perspective view from the top surface, showing each step of the manufacturing method of the mounting structure according to the tenth exemplary embodiment of the present invention;

FIG. 10E is a perspective view from the top surface, showing each step of the manufacturing method of the mounting structure according to the tenth exemplary embodiment of the present invention;

FIG. 11A is a perspective view from the top surface, showing each step of a manufacturing method of the mounting structure according to an eleventh exemplary embodiment of the present invention;

FIG. 11B is a perspective view from the top surface, showing each step of the manufacturing method of the mounting structure according to the eleventh exemplary embodiment of the present invention;

FIG. 11C is a perspective view from the top surface, showing each step of the manufacturing method of the mounting structure according to the eleventh exemplary embodiment of the present invention;

FIG. 11D is a perspective view from the top surface, showing each step of the manufacturing method of the mounting structure according to the eleventh exemplary embodiment of the present invention;

FIG. 12A is a perspective view from the top surface, showing an outline constitution of a mounting structure according to a twelfth exemplary embodiment of the present invention;

FIG. 12B is a partial sectional view taken along the line A-A of FIG. 12A, showing an outline constitution of the mounting structure of the twelfth exemplary embodiment of the present invention;

FIG. 12C is a partial sectional view taken along the line B-B of FIG. 12A, showing an outline constitution of the mounting structure of the twelfth exemplary embodiment of the present invention;

FIG. 13A is a perspective view from the top surface, showing an outline constitution of a mounting structure according to a thirteenth exemplary embodiment of the present invention;

FIG. 13B is a partial sectional view taken along the line A-A of FIG. 13A, showing an outline constitution of the mounting structure of the thirteenth exemplary embodiment of the present invention;

FIG. 13C is a partial sectional view taken along the line B-B of FIG. 13A, showing an outline constitution of the mounting structure of the thirteenth exemplary embodiment of the present invention;

FIG. 14A is a perspective view from the top surface, showing an outline constitution of a mounting structure according to a fourteenth exemplary embodiment of the present invention;

FIG. 14B is a partial sectional view taken along the line A-A of FIG. 13A, showing an outline constitution of the mounting structure of the fourteenth exemplary embodiment of the present invention; and

FIG. 14C is a partial sectional view taken along the line B-B of FIG. 13A, showing an outline constitution of the mounting structure of the fourteenth exemplary embodiment of the present invention.

### EXPLANATION OF REFERENCE

1, 1a SUBSTRATE
11 SOLDER-RESIST
12 ELECTRODE PAD TO BE CONNECT TO A SEMICONDUCTOR PACKAGE
13 ELECTRODE PAD TO BE CONNECTED TO A POWER SUPPLY/GROUND LINE
14 SIGNAL TRANSMISSION LINE
14a POWER SUPPLY/GROUND LINE
15 INSULATING LAYER
16 INSULATING LAYER
17 POWER SUPPLY/GROUND LAYER
18 CLEARANCE
2 SOLDER
3 INSULATING COATING CONDUCTIVE WIRE
31 CONDUCTIVE WIRE
32 INSULATING COATING
33 INSULATING COATING CONDUCTIVE WIRE NET
4, 4a, 4b SEMICONDUCTOR PACKAGE
51, 51a, 51b PACKAGE SUBSTRATE
52, 52a ELECTRODE PAD TO BE CONNECT TO A SEMICONDUCTOR PACKAGE
53a ELECTRODE PAD TO BE CONNECTED TO A POWER SUPPLY/GROUND LINE
54 SIGNAL TRANSMISSION LINE
54a, 54aa POWER SUPPLY/GROUND LINE
55 INSULATING LAYER
56 INSULATING LAYER
57 POWER SUPPLY/GROUND LAYER
58 CLEARANCES
59 INSULATING LAYER
61, 61a SOLDER-RESIST

### BEST MODE FOR CARRYING OUT THE INVENTION

Hereinafter, exemplary embodiments of the present invention will be described with reference to the accompanying drawings.

### First Exemplary Embodiment

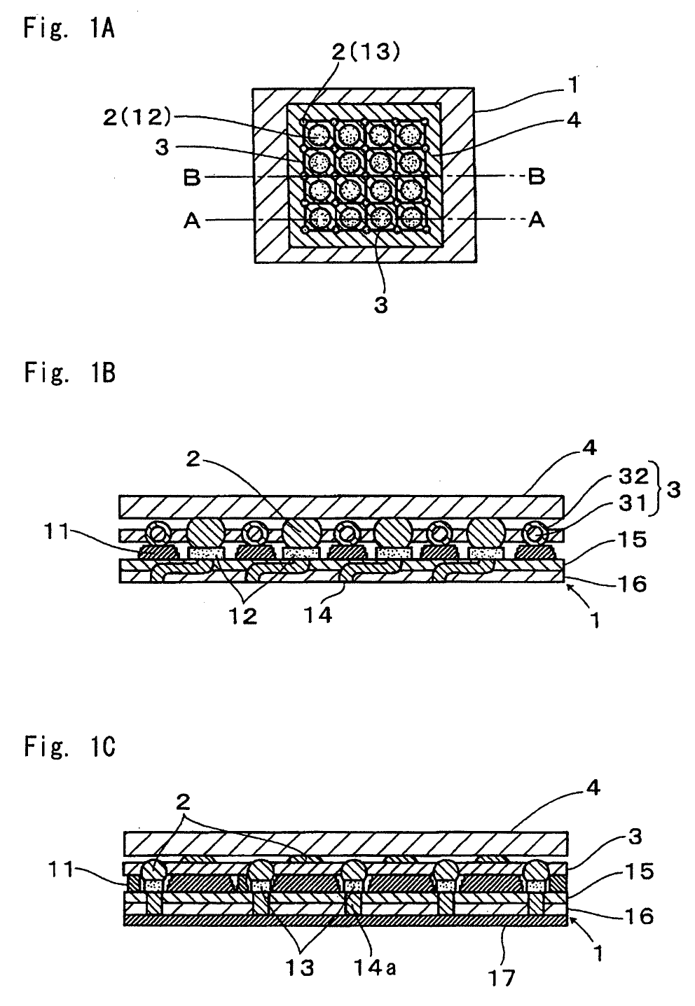

FIGS. 1A to 1C each show a mounting structure according to a first exemplary embodiment of the present invention. FIG. 1A is a perspective view from the top surface, showing an area between a semiconductor package 4 and a substrate 1 constructing the mounting structure. FIGS. 1B and 1C are partial sectional views taken along the lines A-A and B-B of FIG. 1A, respectively.

As shown in FIGS. 1A-1C, the mounting structure of the first exemplary embodiment includes the rectangular substrate 1 and the chip-shaped semiconductor package 4 with a rectangular plane shape mounted on the substrate 1. As shown in FIG. 1A, the size of the semiconductor package 4 is smaller than that of the substrate 1.

The substrate 1 includes two layers of an insulating layer 15 and an insulating layer 16, which are laminated on each other. A plurality of circular electrode pads 12 for mounting the semiconductor package 4, and a plurality of circular electrode pads 13 for mechanically and electrically connecting conductive wires 31 of a plurality of insulating coating conductive wires 3, are formed on the surface of the insulating layer 15 in the surface (upper position) of the substrate 1. The electrode pads 13 are smaller than the electrode pads 12. The part except the electrode pads 12 and the electrode pads 13 formed in the surface of the substrate 1 is covered with an insulating solder-resist film 11. Gaps are formed between the electrode pads 12 and the solder-resist film 11 and between the electrode pads 13 and the solder-resist film 11.

A conductive layer (hereinafter referred to as “power supply/ground layer”) 17, which functions as a power supply layer or a ground layer, is formed in a predetermined pattern on the surface of the insulating layer 16 in back surface (lower position) of the substrate 1

Each of the electrode pads 12 placed in the surface of the substrate 1 has a size corresponding to a plurality of electrode pads (not shown) formed on the back surface of the semiconductor package 4. In the inside of the substrate 1, a plurality of signal transmission lines 14 penetrating through the substrate 1 (i.e., the insulating layer 15 and the insulating layer 16) in the thickness direction thereof are formed. Each upper end of the corresponding signal transmission lines 14 is mechanically and electrically connected to each back surface of the electrode pads 12. Each of the signal transmission lines 14 is electrically connected to a device (not shown) located below the insulating layer 16.

Moreover, in the inside of the substrate 1, a plurality of power supply/ground lines 14a penetrating through the substrate 1 (i.e., the insulating layer 15 and the insulating layer 16) in the thickness direction thereof are formed. Each back surface of the electrode pads 13 is mechanically and electrically connected to each upper end of the corresponding power supply/ground lines 14a. A lower end of each of the power supply/ground lines 14a is mechanically and electrically connected to the power supply/ground layer 17 on the back surface (i.e., the surface of the insulating layer 16) of the substrate 1. Each of the electrode pads 13 placed in the surface of the substrate 1 has a size corresponding to the corresponding power supply/ground line 14a.

The semiconductor package 4 (electrode pads thereof) is mechanically and electrically connected to the corresponding electrode pads 12 on the surface of the substrate 1 through ball-shaped solders 2, and the semiconductor package 4 is thereby implemented above the substrate 1.

The electrode pads 12 are arranged in multiple columns at intervals on the surface of the substrate 1 in a lengthwise direction (a vertical direction in FIG. 1A) and a lateral direction (a transverse direction in FIG. 1A). Herein, the electrode pads 12 are arranged in four columns in the lengthwise direction and in four columns in the lateral direction at substantially regular intervals. In other words, the electrode pads 12 are arranged in a matrix shape having four rows and four columns.

As with the electrode pads 1, the electrode pads 13 are arranged in multiple columns at intervals on the surface of the substrate 1 in a lengthwise direction (vertical direction in FIG. 1A) and a lateral direction (transverse direction in FIG. 1A). Herein, the electrode pads 13 are arranged in five columns in the lengthwise direction and in five columns in the lateral direction at substantially regular intervals. In other words, the electrode pads 13 are arranged in a matrix shape having five rows and five columns. The electrode pads 13 are arranged to surround each of the electrode pads 12. When a square (a rectangle) around each of electrode pads 12 is assumed, the electrode pads 13 are arranged in the four corners of the square.

In addition, ten insulating coating conductive wires 3 are arranged on the surface of the substrate 1. Each the insulating coating conductive wires 3 consists of a conductive wire 31 and an insulating coating 32 coating the perimeter of the conductive wire 31. In this case, because the conductive wire 31 is covered by the insulating coating 32, there is an advantage of preventing a short circuit from occurring due to bridge or the like.

The insulating coating conductive wires 3 are rectilinear, and mechanically and electrically interconnect the five electrode pads 13 that align in a lengthwise direction (a vertical direction in FIG. 1A) or a lateral direction (a transverse direction in FIG. 1A). The insulating coating conductive wires 3 extend in the lengthwise direction or the lateral direction along each row and each column of the matrix of the electrode pads 12 that are arranged in the shape of the matrix of four rows of four columns. They form a lattice that consists of five longitudinal lines and five horizontal lines altogether. As a result, each of the electrode pads 12 is surrounded by a part of the four insulating coating conductive wires 3 placed between two adjacent electrode pads 13. In other words, each of the electrode pads 12 is separated by the insulating coating conductive wires 3. As regarding the electrode pads 13, it can be said that each of the electrode pads 13 is arranged at an intersection of the insulating coating conductive wires 3.

Each of the intersections (i.e., parts with the electrode pads 13) of the insulating coating conductive wires 3 is provided with ball-shaped solders 2. The insulating coatings 32 in each of the insulating coating conductive wires 3 is peeled off at each intersection, and the conductive wires 31 that are placed within the insulating coatings 32 are exposed. Therefore, the two insulating coating conductive wires 3 intersect at each intersection are mechanically and electrically interconnected. In addition, they are mechanically and electrically connected to the corresponding electrode pads 13. Each of the electrode pads 13 is mechanically and electrically connected to the power supply/ground layer 17 in the back surface of the substrate 1 through the corresponding power supply/ground lines 14a. Therefore, all the insulating coating conductive wires 3 are electrically connected to the power supply/ground layer 17.

At each intersection of the insulating coating conductive wires 3, the conductive wires 31 are planarized beforehand. Therefore, the height at each intersection where the two insulating coating conductive wires 3 overlap is not greater than that of the part except the intersection of the insulating coating conductive wires 3. Moreover, the intersecting coating conductive wires 3 are interconnected in a stable state. The cross-sectional shape at each intersection of the conductive wires 31 is not limited to a circle but may be a semi-circle, a rectangle, a square, an ellipse, and so on. The point is that the height at each intersection should be equal to or lower than the height of the insulating coating conductive wire 3.

In a plane view, the shape of the intersection is a cross-shape, an L-shape, or a T-shape as shown in FIG. 1A.

Because the insulating coating conductive wires 3 except the intersections are arranged on the solder-resist 11, the solder-resist 11 has a function to protect the insulating coating conductive wires 3.

The conductive wires 31 of all the insulating coating conductive wires 3 are arranged above the surface of the substrate 1 and are electrically connected to the power supply/ground layer 17 through the electrode pads 13 and the power supply/ground line 14a. Thus, such an effect that unnecessary electromagnetic radiation occurring inside of the mounting structure is inhibited is provided. Moreover, because the conductive wires 31 of all the insulating coating conductive wires 3 are mechanically and electrically connected to the electrode pads 13, which are placed on the surface of the substrate 1, under the semiconductor package 4, the overall stiffness of the mounting structure becomes higher. Therefore, such an effect that the drop impact resistance of the mounting structure improves is also provided.

According to the first exemplary embodiment of the present invention, as mentioned earlier, the mounting structure includes the plurality of electrode pads 12 formed on the surface of the substrate 1 and used to mount the semiconductor package 4 on the substrate 1. In addition, the mounting structure includes the plurality of electrode pads 13 formed on the surface of the substrate 1 and used to electrically interconnect the power supply/ground layer 17 of the substrate 1. Furthermore, the mounting structure includes the conductive wires 31 that are interconnected with at least two points to the electrode pads 13 above the surface of the substrate 1. The interconnection between the semiconductor package 4 and the electrode pads 12 is implemented using the solders 2 as connection materials. The interconnection between the conductive wires 31 and the electrode pads 13 is also implemented using the solders 2 as connection materials.

Thus, because the conductive wires 31 that are interconnected with at least two points to the electrode pads 13, which are electrically interconnected to the power supply/ground layer 17, are provided, unnecessary electromagnetic radiation occurring from a transmission signal that flows through the mounting structure can be inhibited.

Moreover, the stiffness at the front surface side of the substrate 1 can be enhanced without injecting an underfill resin between the semiconductor package 4 and the surface of the substrate 1 because the conductive wires 31 exists above the surface of the substrate 1. Therefore, the drop impact resistance of the mounting structure can be improved.

### Second Exemplary Embodiment

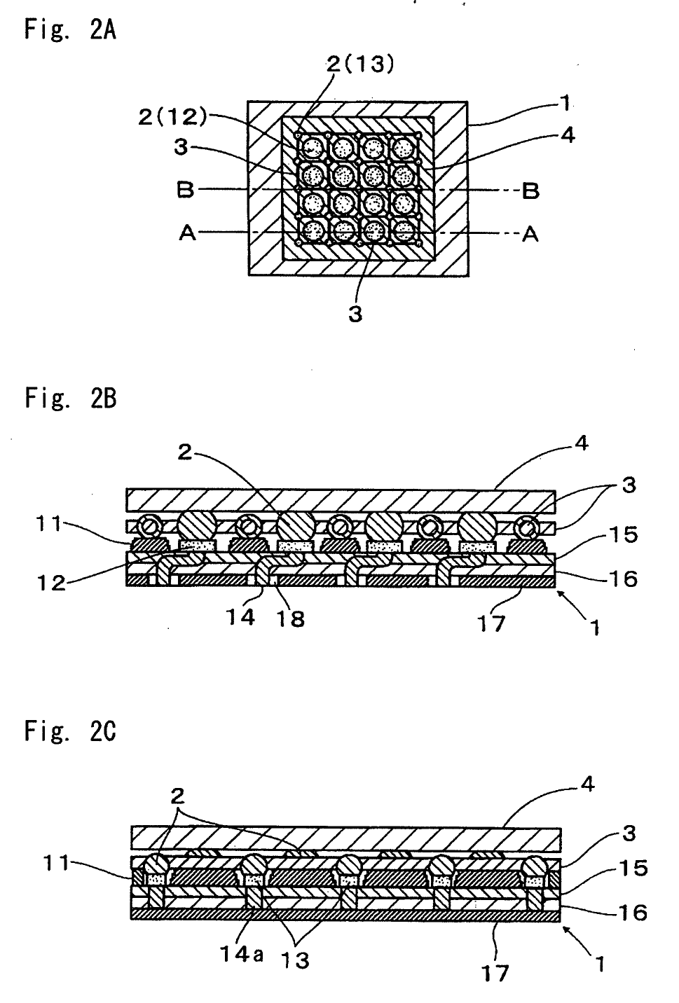

FIGS. 2A to 2C each show a mounting structure according to a second exemplary embodiment of the present invention. FIG. 2A is a perspective view from the top surface, showing an area between the semiconductor package 4 and the substrate 1 constructing the mounting structure. FIGS. 2B and 2C are partial sectional views taken along the lines A-A and B-B of FIG. 2A, respectively.

The mounting structure in accordance with the second exemplary embodiment is structured in the same manner as in the above-described first exemplary embodiment except for the following points. That is, in the part that is exposed to the back surface of the substrate 1 of the plurality of signal transmission lines 14 penetrating through the substrate 1, the power supply/ground layer 17 is formed in the second exemplary embodiment. Each of the signal transmission lines 14 penetrates through the power supply/ground layer 17 and is connected to a packaging device (not shown) below the insulating layer 16. Therefore, in this exemplary embodiment, the parts common to those of the above-described first exemplary embodiment are denoted by the same reference numerals, and explanations thereof are omitted.

As shown in FIG. 2B, between each of the signal transmission lines 14 and the power supply/ground layer 17, clearances 18 are formed. Each conductive wire 31 is placed at a position substantially immediately above (substantially overlaps) the corresponding clearance 18 above the surface of the substrate 1 (on the solder-resist film 11).

In the mounting structure of the second exemplary embodiment, the electrode pads 13, which are placed on the surface of the substrate 1 and electrically connected to the power supply/ground layer 17, are arranged at the position substantially immediately above the clearance 18 between each of the power supply/ground layer 17 and each of the signal transmission lines 17. Accordingly, the return current of the current flowing through the signal transmission line 14 can be drained near the signal transmission line 14. Thus, the mounting structure can provide the same effects as those of the first exemplary embodiment. In addition, the mounting structure can provide such an effect that unnecessary electromagnetic radiation occurring due to the clearance 18 decreases and thus the influence on the other transmission pathways can be reduced.

### Third Exemplary Embodiment

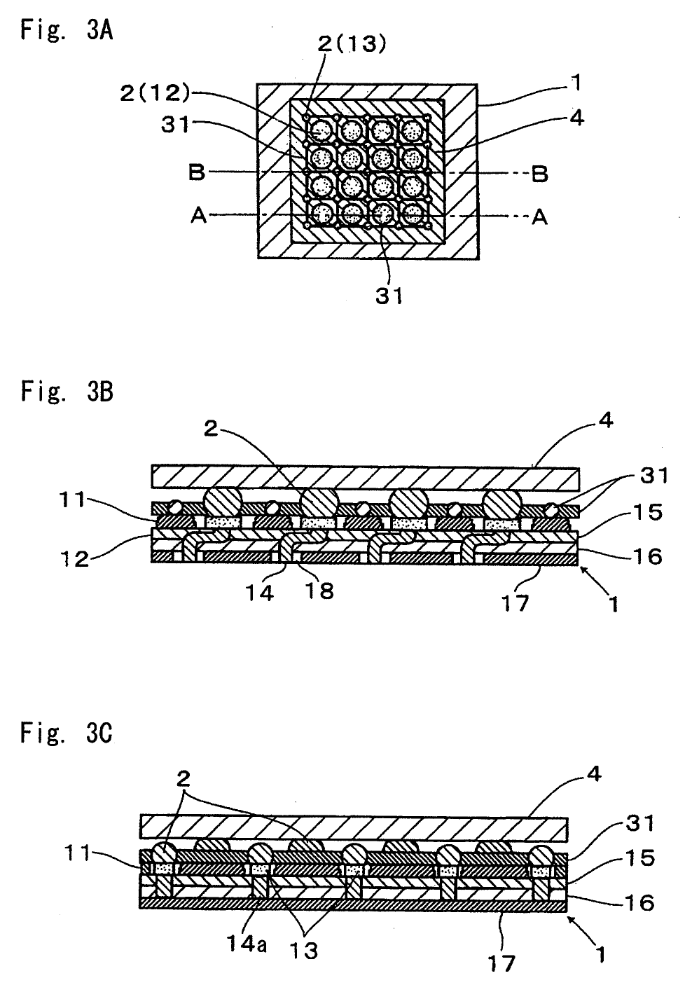

FIGS. 3A to 3C each show a mounting structure according to a third exemplary embodiment of the present invention. FIG. 3A is a perspective view from the top surface, showing an area between the semiconductor package 4 and the substrate 1 constructing the mounting structure. FIGS. 3B and 3C are partial sectional views taken along the lines A-A and B-B of FIG. 3A, respectively.

The mounting structure in accordance with the third exemplary embodiment is structured in the same manner as in the above-described second exemplary embodiment except for the following points. That is, in the third exemplary embodiment, the conductive wires 31 are not coated in an insulating material. Therefore, in this exemplary embodiment, the parts common to those of the above-described second exemplary embodiment are denoted by the same reference numerals, and explanations thereof are omitted.

Because the conductive wire 31 which is not coated in the insulating material is used in the mounting structure of the third exemplary embodiment, the diameter is smaller than that in the case of using the insulating coating conductive wires 3. Therefore, the arrangement interval (pitch) of the electrode pads 12 to be connected to the semiconductor package 4 can be narrowed than that of the second exemplary embodiment. Further, the interval between the semiconductor package 4 and the surface of the substrate 1 can also be made narrower than that of the second exemplary embodiment. Thus, the semiconductor package 4 having a higher-performance semiconductor element can be applied. Therefore, the mounting structure can provide the same effects as those of the second exemplary embodiment, as well as an effect that a higher-performance mounting structure can be provided.

### Fourth Exemplary Embodiment

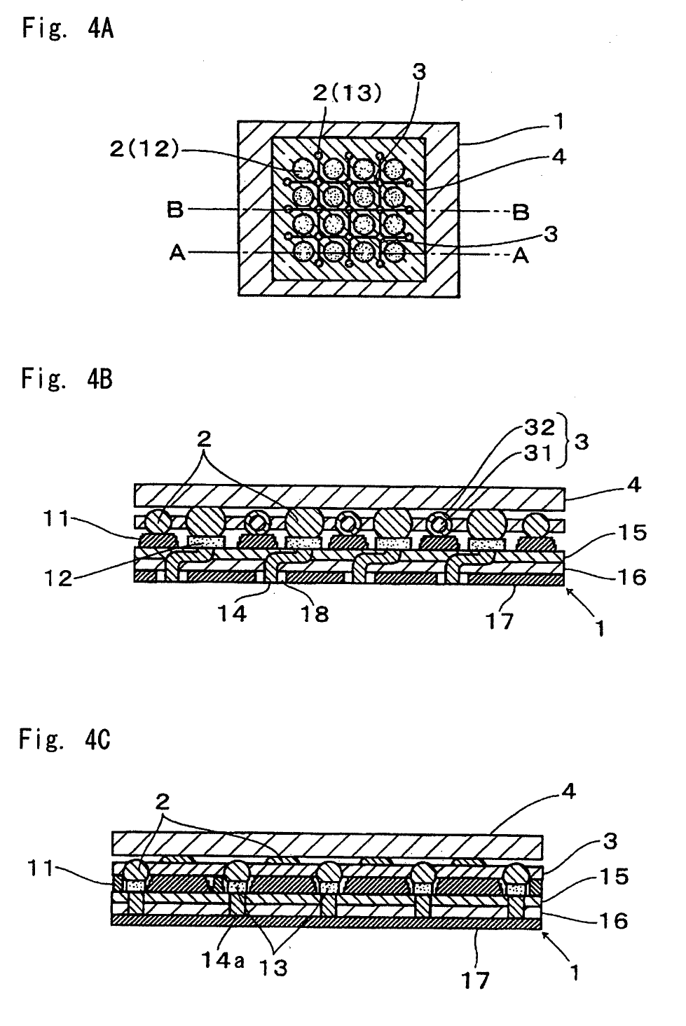

FIGS. 4A to 4C each show a mounting structure according to a fourth exemplary embodiment of the present invention. FIG. 4A is a perspective view from the top surface, showing an area between the semiconductor package 4 and the substrate 1 constructing the mounting structure. FIGS. 4B and 4C are partial sectional views taken along the lines A-A and B-B of FIG. 4A, respectively.

In the mounting structure according to the first to third exemplary embodiments, the insulating coating conductive wires 3 or the conductive wires 31 which are not coated in an insulating material are arranged in the shape of a lattice. However, in the present invention, they are not necessarily being arranged in the shape of a lattice.

Therefore, in the mounting structure of the fourth exemplary embodiment, four insulating coating conductive wires 3, which are arranged in the four sides of the bounds of the matrix, are removed from the ten insulating coating conductive wires 3, which are arranged along the matrix having five rows and five columns of the electrode pads 13 in the second exemplary embodiment. In response to this, the electrode pads 13 (four) arranged in the four outer circumferential corners of the matrix are also removed. The mounting structure of the fourth exemplary embodiment is constituted in the same manner as the mounting structure of the second exemplary embodiment except for these points. Therefore, the parts common to those of the above-described second exemplary embodiment are denoted by the same reference numerals, and explanations thereof are omitted.

Because the mounting structure of the fourth exemplary embodiment has the above-mentioned constitution, the number of steps to mount the insulating coating conductive wires 3 on the electrode pads 13 by a loader decreases. Therefore, the mounting structure can provide the same effects as those of the second exemplary embodiment, as well as an effect that the number of the mounting processes of the insulating coating conductive wires 3 can be reduced and the material cost can be reduced along with a reduction in usage of the insulating coating conductive wires 3, leading to a reduction in production cost.

### Fifth Exemplary Embodiment

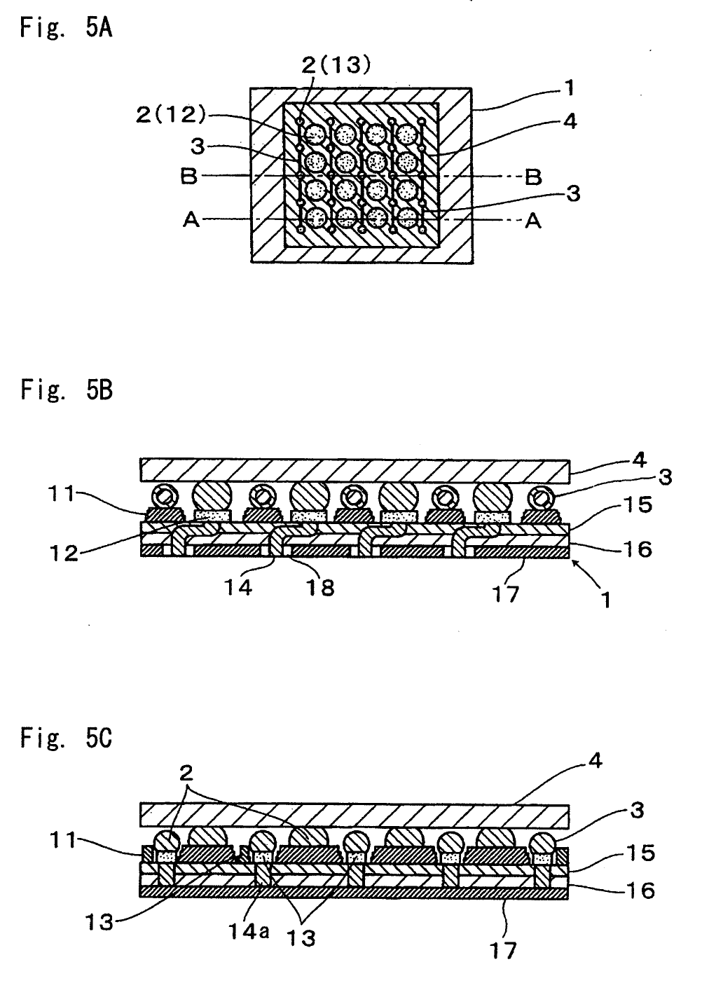

FIGS. 5A to 5C each show a mounting structure according to a fifth exemplary embodiment of the present invention. FIG. 5A is a perspective view from the top surface, showing an area between the semiconductor package 4 and the substrate 1 constructing the mounting structure. FIGS. 5B and 5C are partial sectional views taken along the lines A-A and B-B of FIG. 5A, respectively.

In the mounting structure of the fifth exemplary embodiment, five insulating coating conductive wires 3, which are extended in the bilateral direction of the matrix, are removed from the ten insulating coating conductive wires 3, which are placed along the matrix of five lines of five lines of electrode pads 13 in the second exemplary embodiment. In other words, the five insulating coating conductive wires 3 are arranged only in the vertical direction of the matrix. The mounting structure of the fifth exemplary embodiment is constitution same as mounting structure of the second exemplary embodiment except this point. Therefore, the parts common to those of the above-described second exemplary embodiment are denoted by the same reference numerals, and explanations thereof are omitted.

Because the mounting structure of the fifth exemplary embodiment has the above-mentioned constitution, the number of steps to mount the insulating coating conductive wires 3 on the electrode pads 13 by a loader decreases. Therefore, the mounting structure can provide the same effects as those of the second exemplary embodiment, as well as an effect that the number of the mounting processes of the insulating coating conductive wires 3 can be reduced and the material cost can be reduced along with a reduction in usage of the insulating coating conductive wires 3, leading to a reduction in production cost.

Note that, in the fifth exemplary embodiment, though the five insulating coating conductive wires 3 are arranged along the matrix having five rows of five columns of the electrode pads 13, at least one insulating coating conductive wire 3 is sufficient. Thus, among the five insulating coating conductive wires 3, four of them may be omitted.

### Sixth Exemplary Embodiment

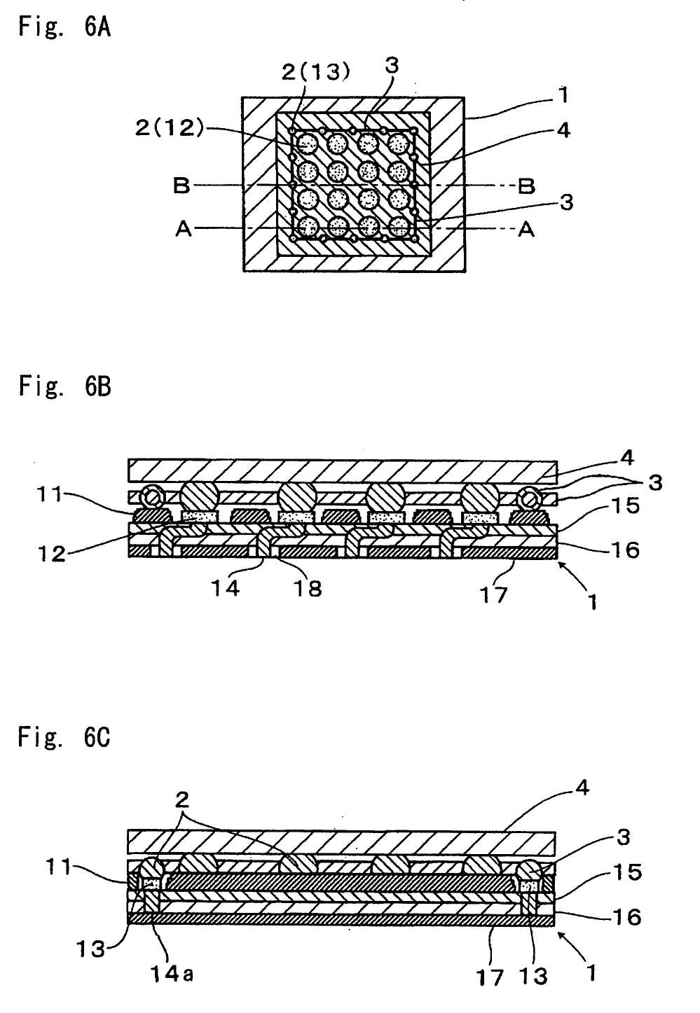

FIGS. 6A to 6C each show a mounting structure according to a sixth exemplary embodiment of the present invention. FIG. 6A is a perspective view from the top surface, showing an area between the semiconductor package 4 and the substrate 1 constructing the mounting structure. FIGS. 6B and 6C are partial sectional views taken along the lines A-A and B-B of FIG. 6A, respectively.

In the mounting structure of the sixth exemplary embodiment, among the ten insulating coating conductive wires, which are arranged along the matrix having five rows and five columns of the electrodes 13 in the second exemplary embodiment, four insulating coating conductive wires 3 extending along the bounds of the matrix are left, and the remaining six insulating coating conductive wires 3 are removed. In other words, the five insulating coating conductive wires 3 are arranged only along the bounds of the matrix. The mounting structure of the sixth exemplary embodiment is constructed in the same manner as the mounting structure of the second exemplary embodiment except for this point. Therefore, the parts common to those of the above-described second exemplary embodiment are denoted by the same reference numerals, and explanations thereof are omitted.

Because the mounting structure of the sixth exemplary embodiment has the above-mentioned constitution, the number of steps to mount the insulating coating conductive wires 3 on the electrode pads 13 by a loader decreases. Therefore, the mounting structure can provide the same effects as those of the second exemplary embodiment, as well as an effect that the number of the mounting processes of the insulating coating conductive wires 3 can be reduced and the material cost can be reduced along with a reduction in usage of the insulating coating conductive wires 3, leading to a reduction in production cost.

### Seventh Exemplary Embodiment

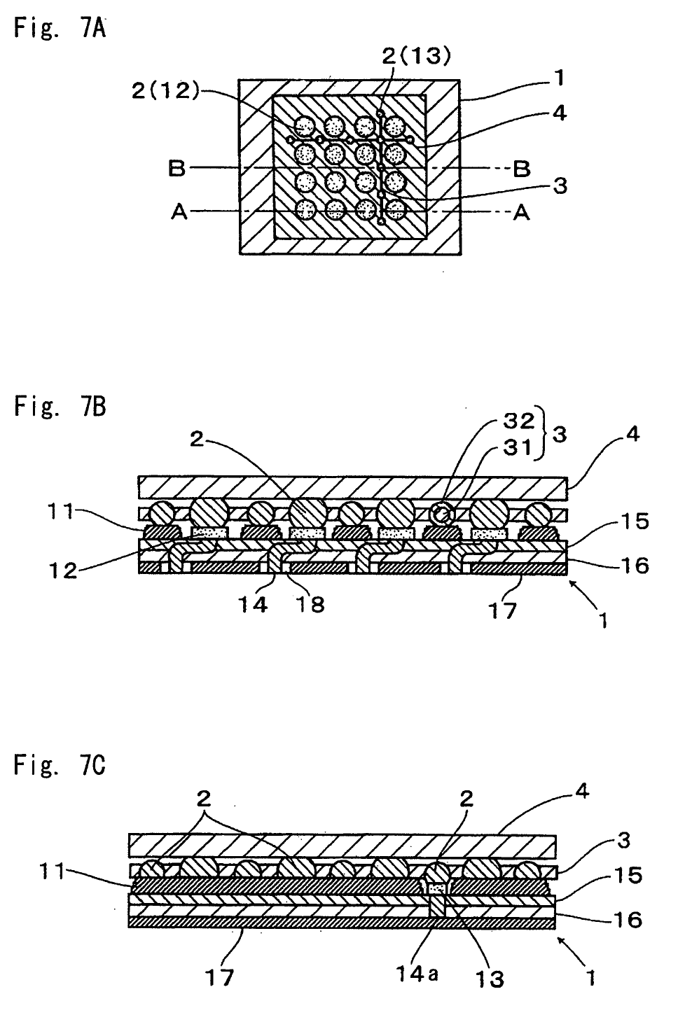

FIGS. 7A to 7C each show a mounting structure according to a seventh exemplary embodiment of the present invention. FIG. 7A is a perspective view from the top surface, showing an area between the semiconductor package 4 and the substrate 1 constructing the mounting structure. FIGS. 7B and 7C are partial sectional views taken along the lines A-A and B-B of FIG. 7A, respectively.

In the mounting structure of the seventh exemplary embodiment, among the ten insulating coating conductive wires 3, one insulating coating conductive wire 3 extending in the top and bottom direction of the matrix and one insulating coating conductive wire 3 extending in the bilateral direction of the matrix are left, and the remaining eight insulating coating conductive wires 3 are removed. In other words, one insulating coating conductive wire 3 is arranged in each of the top and bottom direction and the bilateral direction of the matrix. The mounting structure of the seventh exemplary embodiment is constructed in the same manner as the mounting structure of the second exemplary embodiment except for these points. Therefore, in this exemplary embodiment, the parts common to those of the above-described second exemplary embodiment are denoted by the same reference numerals, and explanations thereof are omitted.

Because the mounting structure of the seventh exemplary embodiment has the above-mentioned constitution, the number of steps to mount the insulating coating conductive wires 3 on the electrode pads 13 by a loader decreases. Therefore, the mounting structure can provide the same effects as those of the second exemplary embodiment, as well as an effect that the number of the mounting processes of the insulating coating conductive wires 3 can be reduced and the material cost can be reduced along with a reduction in usage of the insulating coating conductive wires 3, leading to a reduction in production cost.

Note that, in the seventh exemplary embodiment, though one insulating coating conductive wire 3 is arranged in each of the top and bottom direction and the bilateral direction of the matrix, the insulating coating conductive wires 3 may be added to the top and bottom direction or the bilateral direction of the matrix.

### Eighth Exemplary Embodiment

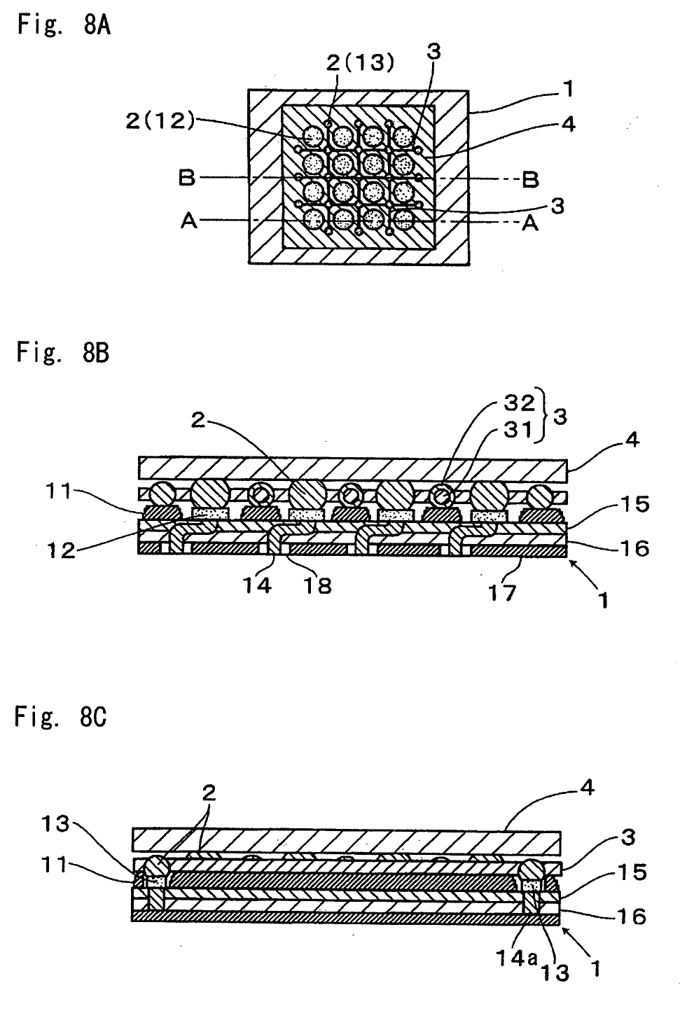

FIGS. 8A to 8C each show a mounting structure according to an eighth exemplary embodiment of the present invention. FIG. 8A is a perspective view from the top surface, showing an area between the semiconductor package 4 and the substrate 1 constructing the mounting structure. FIGS. 8B and 8C are partial sectional views taken along the lines A-A and B-B of FIG. 8A, respectively.

In the mounting structure of the eighth exemplary embodiment, the electrode pads 13 and the power supply/ground lines 14a that are placed at both ends of each of eight insulating coating conductive wires 3 arranged in the shape of the matrix having five rows and five columns of the fourth exemplary embodiment are left, and the remaining electrode pads 13, and power supply/ground lines 14a except them are omitted. This is because it is sufficient that the insulating coating conductive wires 3 are electrically connected to the power supply/ground layer 17 through the electrode pads 13 and the power supply/ground lines 14a in at least two points. The mounting structure of the eighth exemplary embodiment is constructed in the same manner as the mounting structure of the above-mentioned fourth exemplary embodiment except for these points. Therefore, the parts common to those of the above-described fourth exemplary embodiment are denoted by the same reference numerals, and explanations thereof are omitted.

Because the mounting structure of the eighth exemplary embodiment has the above-mentioned constitution, the number of steps to mount the insulating coating conductive wires 3 on the electrode pads 13 by a loader decreases. Therefore, the mounting structure can provide the same effects as those of the fourth exemplary embodiment, as well as an effect that the number of the mounting processes of the insulating coating conductive wires 3 can be reduced and the material cost can be reduced along with a reduction in number of the insulating coating conductive wires 3 and in usage of the solders 2 insulating coating conductive wires 3, leading to a reduction in production cost.

### Ninth Exemplary Embodiment

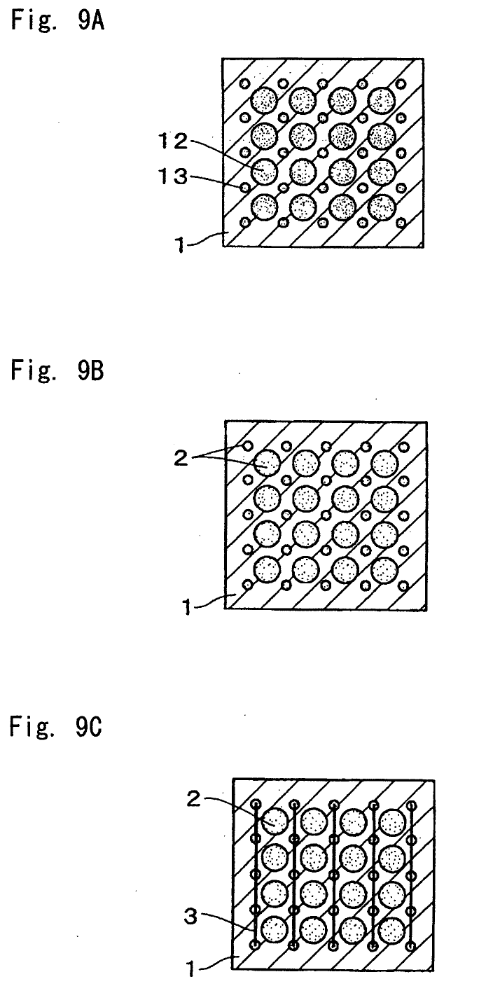

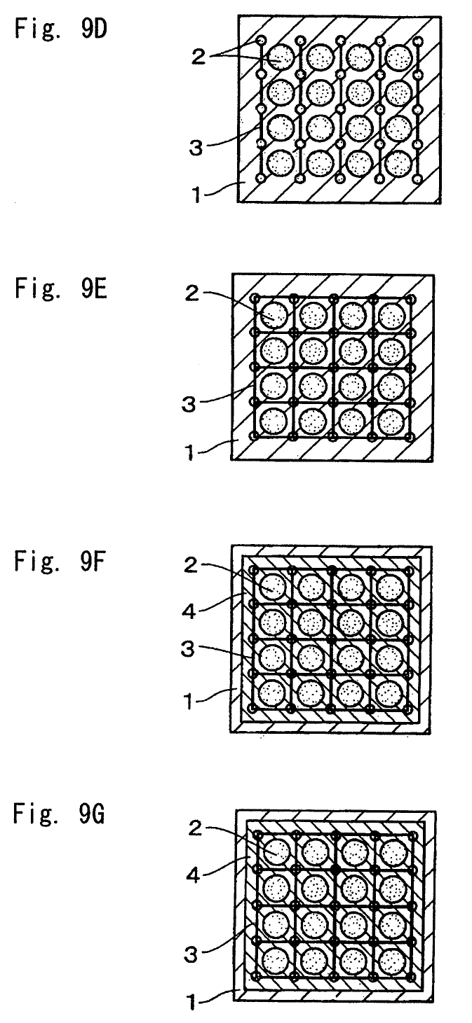

FIGS. 9A to 9G each show a manufacturing method of the mounting structure according to a ninth exemplary embodiment of the present invention. FIGS. 9A to 9G are sectional views showing the manufacturing method in the order of steps. In this exemplary embodiment, because the mounting structure of the above-mentioned first exemplary embodiment is produced, the parts common to those of the above-described first exemplary embodiment are denoted by the same reference numerals, and explanations thereof are omitted.

First, there is prepared the substrate 1 having, formed on the surface thereof, the electrode pads 12, which are arranged in the shape of the matrix having four rows and four columns, and the electrode pads 13, which are arranged in the shape of the matrix having five rows and five columns. The state of the substrate 1 at this time is shown in FIG. 9A. However, the solder-resist film 11 is omitted.

Then, as shown in FIG. 9B, a predetermined amount of the pasty solder 2 is supplied (put) on the electrode pads 12 and the electrode pads 13 placed on the surface of the substrate 1.

Next, the five insulating coating conductive wires 3 are mounted in the lengthwise direction (or the lateral direction) so as to overlap the solder 2 on the electrodes 13. The state at this time is shown in FIG. 9C.

Then, to an intersection between the insulating coating conductive wires 3 that have been mounted and the insulating coating conductive wires 3 to be subsequently mounted, the predetermined amount of the pasty solder 2 is supplied (put). The state at this time is shown in FIG. 9D.

Next, the other five insulating coating conductive wires 3 are placed in the lateral direction (or the lengthwise direction.) so as to overlap the solders 2 on the electrodes 13. The state at this time is shown in FIG. 9E. The insulating coating conductive wires 3 are in the shape of a lattice.

Subsequently, the semiconductor package 4 is mounted so as to overlap the solders 2 on the electrode pads 12. The state at this time is shown in FIG. 9F.

Finally, a solder reflow process is carried out on the layer stack of the substrate 1 and the semiconductor package 4. After making the solders 2 melt temporarily, the solders 2 are cured. As a result, the semiconductor package 4 is implemented above the surface of the substrate 1 through the electrode pads 12. At the same time, the insulating coating conductive wires 3 are implemented in the shape of a lattice above the surface of the substrate 1 through the electrode. pads 13. In this way, the mounting structure of the first exemplary embodiment is provided.

The manufacturing method of the mounting structure of the ninth exemplary embodiment is carried out by the above-mentioned process, and thus can be carried out without largely changing a conventional packaging process.

Note that it goes without saying that the mounting structure of the second to eighth exemplary embodiments can be manufactured by this manufacturing method.

### Tenth Exemplary Embodiment

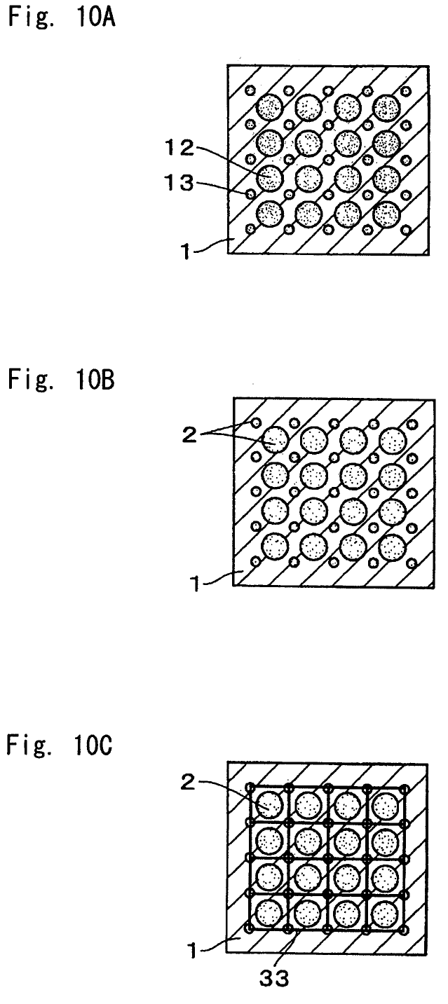

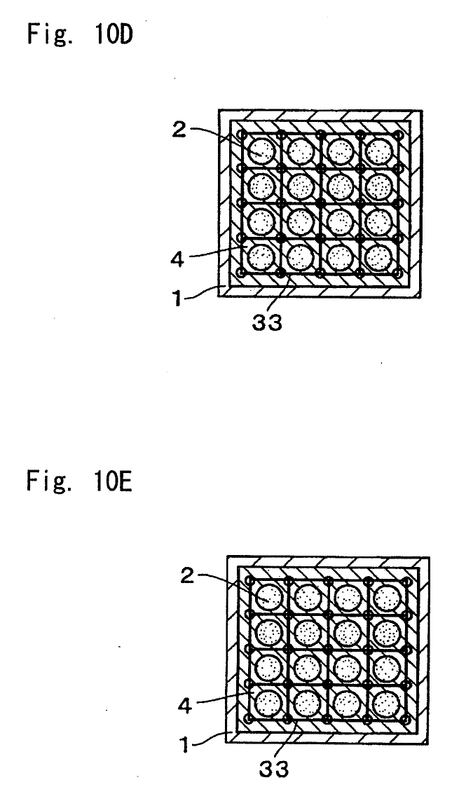

FIGS. 10A to 10E each show a manufacturing method of the mounting structure according to a tenth exemplary embodiment of the present invention. FIGS. 10A to 10E are sectional views showing the manufacturing method in the order of steps. This exemplary embodiment is identical to the manufacturing method of the mounting structure of the ninth exemplary embodiment except for the following point. That is, in the step of mounting the insulating coating conductive wires 3 in the manufacturing method of the ninth exemplary embodiment, an insulating coating conductive wire network 33 formed such that ten insulating coating conductive wires 3 (which may not be coated in an insulating material) are intersected and jointed in the shape of a lattice beforehand is used.

At first, like the above-mentioned ninth exemplary embodiment, there is prepared the substrate 1 having, formed on the surface thereof, the electrode pads 12, which are arranged in the shape of the matrix having four rows and four columns, and the electrode pads 13, which are arranged in the shape of the matrix having five rows and five columns (FIG. 10A). Then, the predetermined amount of the pasty solder 2 is supplied (put) on the electrode pads 12 and the electrode pads 13 placed on the surface of the substrate 1 (FIG. 10A).

Then, the insulating coating conductive wire network 33 is mounted on the solders 2 placed on the electrode pads 13 (FIG. 10C). The insulating coating conductive wire network 33 consists of ten insulating coating conductive wires 3, which are intersected and joined in the shape of a lattice.

Thereafter, to intersections of the insulating coating conductive wires 3 that compose the insulating coating conductive wire network 33, the predetermined amount of the pasty solder 2 is supplied (put) (FIG. 10D). Then, the semiconductor package 4 is mounted so as to overlap the solders 2 on the electrode pads 12.

Finally, when a solder reflow process is carried out as in the ninth exemplary embodiment, the mounting structure of the first exemplary embodiment is provided.

The manufacturing method of the mounting structure of the tenth exemplary embodiment is carried out by the above-mentioned process, and thus can be carried out without largely changing a conventional packaging process.

Note that the insulating coating conductive wire network 33 may be formed by spot processing using lasers.

### Eleventh Exemplary Embodiment

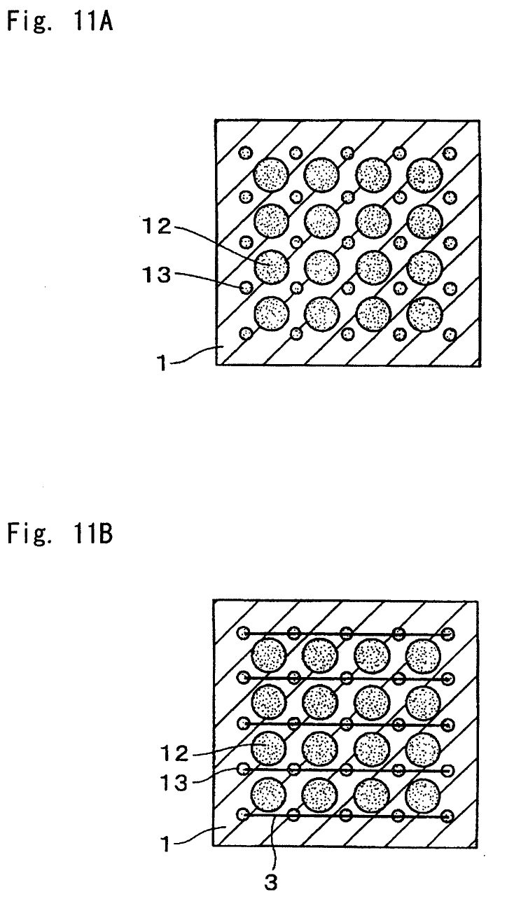

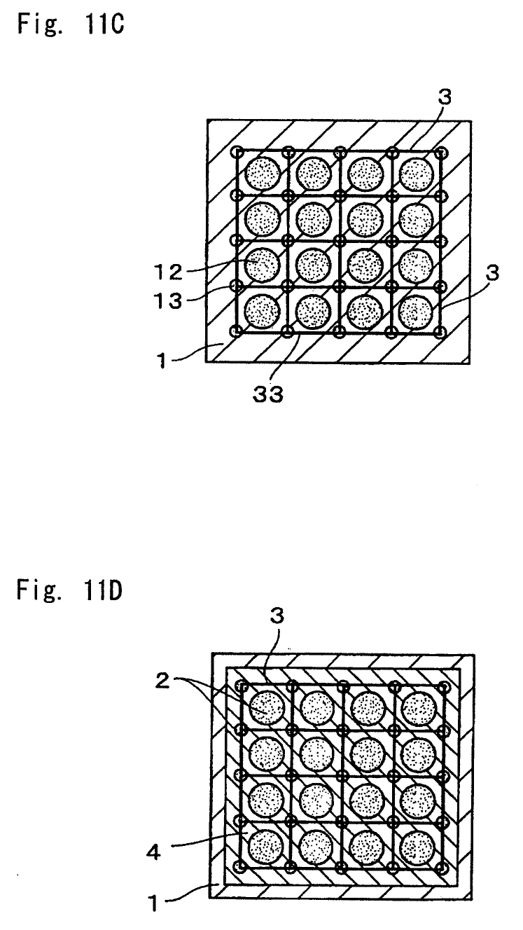

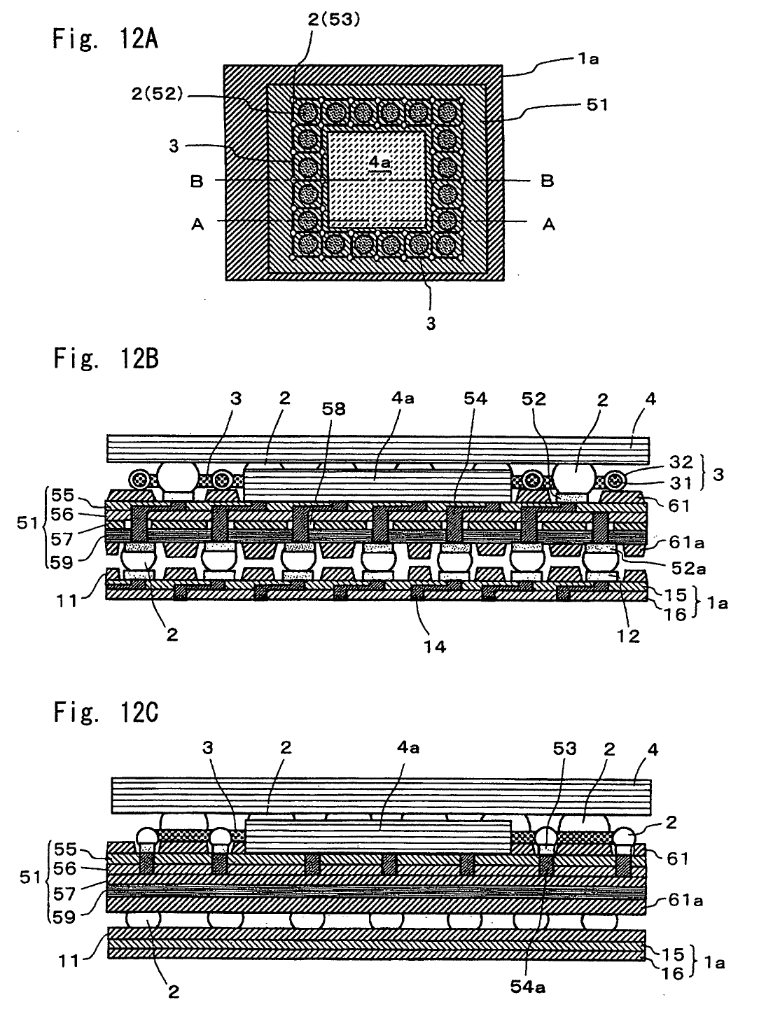

FIGS. 11A to 11D each show a manufacturing method of the mounting structure according to an eleventh exemplary embodiment of the present invention. FIGS. 11A to 11D are sectional views showing the manufacturing method in the order of steps. This exemplary embodiment is identical to the manufacturing method of the mounting structure of the ninth exemplary embodiment except for the following point. That is, in the step of mounting the insulating coating conductive wires 3 in the manufacturing method of the ninth exemplary embodiment, the insulating coating conductive wires 3 (which may not be coated in an insulating material) are mechanically and electrically connected onto the electrode pads 13 by laser welding.

At first, like the above-mentioned ninth exemplary embodiment, there is prepared the substrate 1 having, formed on the surface thereof, the electrode pads 12, which are arranged in the shape of the matrix having four rows and four columns, and the electrode pads 13, which are arranged in the shape of the matrix having five rows and five columns (FIG. 11A). Then, the five insulating coating conductive wires 3 are mounted in the lateral direction (or the lengthwise direction.) so as to overlap with the electrode pads 13. Further, by laser welding, these insulating coating conductive wires 3 are connected onto the electrode pads 13. This state at this time is shown in FIG. 11B.

Next, the other five insulating coating conductive wires 3 are mounted in the lengthwise direction (or the lateral direction.) so as to overlap the electrode pads 13. Further, by laser welding, these insulating coating conductive wires 3 are connected onto the electrode pads 13. The state at this time is shown in FIG. 11C. The insulating coating conductive wires 3 are in the shape of a lattice.

Then, after mounting the solders 2 on the electrode pads 12, the semiconductor package 4 is mounted so as to overlap the solders 2. Finally, like the ninth exemplary embodiment, a solder reflow process is carried out, and the semiconductor package 4 is implemented above the surface of the substrate 1 through the electrode pads 12. In this way, the mounting structure of the first exemplary embodiment is provided.

The manufacturing method of the mounting structure of the eleventh exemplary embodiment is carried out by the above-mentioned process, and thus can be manufactured without largely changing a conventional packaging process.

Note that, in the step of mounting the semiconductor package 4, the press contact method that is generally used in the packaging process of electronic devices may be used.

### Twelfth Exemplary Embodiment

FIGS. 12A to 12C each show a mounting structure according to a twelfth exemplary embodiment of the present invention. FIG. 12A is a perspective view from the top surface, showing an area between a semiconductor package 4a and a package substrate 51 constructing the mounting structure. FIGS. 12B and 12C are partial sectional views taken along the lines A-A and B-B of FIG. 12A, respectively.

As shown in FIGS. 12A to 12C, the mounting structure of the twelfth exemplary embodiment includes a rectangular substrate 1a, the package substrate 51 with a rectangular plane shape mounted on the substrate 1a, and the chip-shaped semiconductor package 4 with a rectangular plane shape mounted on the substrate 1. On the surface of the package substrate 51, the chip-shaped semiconductor package 4a with a rectangular plane shape. As shown in FIG. 12A, the size of the package substrate 51 is smaller than the substrate 1. The size of the semiconductor package 4a is smaller than the package substrate 51. Moreover, the semiconductor package 4a has substantially the same size as the package substrate 51.

Thus, the mounting structure of the twelfth exemplary embodiment uses the package substrate 51 including the semiconductor package 4a in substitution for the substrate 1 in the mounting structure of the first exemplary embodiment, and corresponds to one in which the substrate 1a is additionally mounted to the back surface of the package substrate 51 (i.e., the major plane on the opposite side of the semiconductor package 4). Further, because the semiconductor package 4 is mounted so as to overlap the semiconductor package 4a, this mounting structure becomes the Package-On-Package (PoP) structure.

The substrate 1a, like the substrate 1 used in the first exemplary embodiment, includes two layers of the insulating layer 15 and the insulating layer 16, which are laminated on each other. The plurality of circular electrode pads 12, which are provided to mount the package substrate 51, are formed on the surface of the substrate 1a (i.e., the surface of the insulating layer 15 located in the upper layer). Herein, the electrode pads 12 are arranged in seven columns in the lengthwise direction (vertical direction in FIG. 12A) and in seven columns in the lateral direction (transverse direction in FIG. 12A) at substantially regular intervals on the surface of the substrate 1a. In other words, the electrode pads 12 are arranged in the shape of the matrix having seven rows and seven columns. Each of the electrode pads 12 has a size corresponding to a plurality of electrode pads 52a formed on the back surface of the package substrate 51.

The electrode pads 13 used to mechanically and electrically connect the conductive wires 31 of the insulating coating conductive wires 3 are not formed on the surface of the substrate 1a. This is because the insulating coating conductive wires 3 (or the conductive wires 32) are not arranged above the surface of the substrate 1a. The part except the electrode pads 12 formed on the surface of the substrate 1 is covered with the insulating solder-resist film 11. Gaps are formed between each of the electrode pads 12 and the solder-resist film 11. The power supply/ground layer 17 is not formed in the back surface of the substrate 1a (i.e., the surface of the insulating layer 16 located in the lower layer). This is because the insulating coating conductive wires 3 (or the conductive wires 32) are not arranged above the substrate 1a.

In the inside of the substrate 1a, the plurality of signal transmission lines 14 penetrating through the substrate 1a (i.e., the insulating layer 15 and the insulating layer 16) in the thickness direction thereof are formed in a predetermined pattern. Upper ends of the corresponding signal transmission lines 14 are mechanically and electrically connected to each back surface of the electrode pads 12. Each of the signal transmission lines 14 is electrically connected to a device (not shown) disclosed below the insulating layer 16.

The power supply/ground line 14a is not formed inside the substrate 1a. This is because the power supply/ground layer 17 to be connected with the power supply/ground line 14a is not formed in the back surface of substrate 1a.

The electrode pads 12 on the surface of the substrate 1a, and the corresponding electrode pads 52a of the package substrate 51 are mechanically and electrically interconnected through the ball-shaped solders 2, and the package substrate 51 is thereby implemented on the substrate 1.

The package substrate 51 is constituted by laminating an insulating layer 55, an insulating layer 56, a power supply/ground layer 57 (this has a predetermined pattern), and an insulating layer 59 in this order. At the central part of the surface (i.e., the surface of the insulating layer 55) of the package substrate 51, the semiconductor package 4a is implemented.

A plurality of circular electrode pads 52, which are provided to mount the semiconductor package 4, and a plurality of circular electrode pads 53, which are provided to mechanically and electrically connect the conductive wires 31 of the plurality of insulating coating conductive wires 3, are formed on the surface of the package substrate 51 so as to surround the semiconductor package 4a. The electrode pads 53 are smaller than the electrode pads 52. The part except the electrode pads 52, the electrode pads 53, and the semiconductor package 4a formed on the surface of the package substrate 51 is covered with an insulating solder-resist film 61. Gaps are formed between each of the electrode pads 52 and 53 and the solder-resist film 61, and between the semiconductor package 4a and the solder-resist film 61. Each of the electrode pads 52 has a size corresponding to a plurality of electrode pads (not shown) formed on the back surface of the semiconductor package 4 which is located in the uppermost layer of the mounting structure.

The back surface (i.e., the surface of the insulating layer 59) of the package substrate 51 is provided with the electrode pads 52a to be connected with the substrate 1a as described above. The part except the electrode pads 52a formed on the back surface of the package substrate 51 is covered with an insulating solder-resist film 61a. Gaps are formed between each of the electrode pads 52a and the solder-resist film 61a.

In the inside of the package substrate 51, a plurality of signal transmission lines 54 penetrating through the package substrate 51 (i.e., the insulating layers 55 and 56, the power supply /ground layer 57, and the insulating layer 59) in the thickness direction thereof are formed. The upper ends of the corresponding signal transmission lines 54 are mechanically and electrically connected to each back surface of the electrode pads 52 and each of electrode pads (not shown) of the semiconductor package 4a. The signal transmission lines 54 are electrically connected to the corresponding electrode pads 52a on the back surface of the package substrate 51.

Moreover, in the inside of the package substrate 51, a plurality of power supply/ground lines 54a penetrating through the insulating layers 15 and 16 in the thickness direction thereof are formed. Each back surface of the electrode pads 53 is mechanically and electrically connected to the upper end of the corresponding power supply/ground line 54a. The lower end of each of the power supply/ground lines 54a is mechanically and electrically connected to the power supply/ground layer 57 in the package substrate 51. Each of the electrode pads 53 arranged in the surface of the package substrate 51 has a size corresponding to the corresponding power supply/ground line 54a.

A plurality of electrode pads (not shown) of the semiconductor package 4 and the corresponding electrode pads 52 on the surface of the package substrate 51 are mechanically and electrically interconnected through the ball-shaped solders 2. Thus, the semiconductor package 4 is implemented on the package substrate 51 so as to overlap the semiconductor package 4a. There is a gap between the opposing surfaces of the semiconductor package 4 and the semiconductor package 4a, and the packages 4 and 4a are not interconnected.

The semiconductor package 4 is electrically connected to a device (not shown) which is disposed below the substrate 1a through the solders 2 and the electrode pads 52 on the surface of the package substrate 51, the signal transmission lines 54 in the package substrate 51, the solders 2 and the electrode pads 52a on the back surface of the package substrate 51, the electrode pads 12 on the surface of the substrate 1a, and the signal transmission lines 14 in the substrate 1a. Similarly, the semiconductor package 4a is electrically connected to the above-mentioned device through the signal transmission lines 54 in the package substrate 51, the solders 2 and the electrode pads 52a on the back surface of the package substrate 51, the electrode pads 12 on the surface of the substrate 1a, and the signal transmission lines 14 in the substrate 1a.

The electrode pads 52 placed on the surface of the package substrate 51 are arranged in one column in the lengthwise direction (vertical direction in FIG. 12A) and in one column in the lateral direction (transverse direction in FIG. 12A) at substantially regular intervals around the semiconductor package 4a. This is equivalent to a structure in which four columns in the lengthwise direction and four columns in the lateral direction that are located at the center are removed from the matrix having six columns in the lengthwise direction and six columns in the lateral direction, and in which the semiconductor package 4a is disposed in the removed part.

Like the electrode pads 52, the electrode pads 53 on the surface of the package substrate 51 are also arranged in two columns in the lengthwise direction and in two columns in the lateral direction at substantially regular intervals. This is equivalent to a structure in which three columns in the lengthwise direction and three columns in the lateral direction that are located at the center are removed from the matrix having seven columns in the lengthwise direction and seven columns in the lateral direction. The electrode pads 53 are arranged so as to surround each of the electrode pads 52. In other words, when a square (a rectangle) around each of electrode pads 52 is assumed, the electrode pads 53 are arranged in four corners the square.

In addition, the plurality of the insulating coating conductive wires 3 are arranged above the surface (on the solder-resist 61) of the package substrate 51. Each insulating coating conductive wire 3 is similar to that used in the above-mentioned first exemplary embodiment. The insulating coating conductive wires 3 are rectilinear, and mechanically and electrically interconnect electrode pads 53a aligning in the lengthwise direction or the lateral direction. This is equivalent to the following. That is, in the insulating coating conductive wires 3, from the matrix having seven columns in the lengthwise direction and seven columns in the lateral direction, three columns in the lengthwise direction and three columns in the lateral direction placed at the center thereof are removed. Each of the electrode pads 52 is surrounded by a part of the four insulating coating conductive wires 3 placed between two adjacent electrode pads 53. In other words, each of the electrode pads 52 is separated by the insulating coating conductive wires 3. As regarding the electrode pads 53, it can be said that each of the electrode pads 53 is placed at each intersection of the insulating coating conductive wires 3.

Each of the intersections (i.e., parts with the electrode pads 53) of the insulating coating conductive wires 3 is provided with the ball-shaped solders 2. In the insulating coating conductive wires 3, the insulating coatings 32 are peeled off at the intersections, and the conductive wires 31 that are placed inside the insulating coatings 32 are exposed. Therefore, two insulating coating conductive wires 3 intersecting at the intersection are interconnected mechanically and electrically, and are mechanically and electrically connected to the corresponding electrode pads 53. Each electrode pad 53 is mechanically and electrically connected to the power supply/ground layer 57 in the package substrate 51 through the corresponding the power supply/ground lines 54a. Therefore, all the insulating coating conductive wires 3 are electrically connected to the power supply/ground layer 57.

Like the first exemplary embodiment, at each intersection of the insulating coating conductive wires 3, the conductive wires 31 are planarized beforehand. Therefore, the height at each intersection where the two insulating coating conductive wires 3 overlap each other is not greater than that of the part except the intersection of the insulating coating conductive wires 3. Moreover, the intersecting insulating coating conductive wires 3 are interconnected in a stable state. In a plane view, the shape of the intersection is an L-shape or a T-shape as shown in FIG. 12A.

The conductive wires 31 of all the insulating coating conductive wires 3 are placed above the surface of the package substrate 51 and are electrically connected to the power supply/ground layer 57 through the electrode pads 53 and the power supply/ground lines 54a. Thus, the effect that unnecessary electromagnetic radiation occurring inside the mounting structure is inhibited is provided. Moreover, because the conductive wires 31 of all the insulating coating conductive wires 3 are mechanically and electrically connected to the electrode pads 53, which are placed on the surface of the package substrate 51, under the semiconductor package 4, the overall stiffness of the mounting structure becomes higher. Therefore, the effect that the drop impact resistance of the mounting structure improves is provided.

According to the twelfth exemplary embodiment of the present invention, as mentioned earlier, the mounting structure includes the plurality of electrode pads 52 formed on the surface of the package substrate 51 and used to mount the semiconductor package 4 above the package substrate 51. In addition, the mounting structure includes the plurality of electrode pads 53 formed on the surface of the package substrate 51 and used to electrically connect the power supply/ground layer 57 on the substrate. Furthermore, the mounting structure includes the conductive wires 31 that are connected with at least two points to the electrode pads 53 on the surface of the package substrate 51. The interconnection between the semiconductor package 4 and electrode pads 52 is carried out using the solders 2 as connection materials. The interconnection between the conductive wires 31 and the electrode pads 13 is also carried out using the solders 2 as connection materials.

Thus, because the conductive wires 31 that are connected with at least two points to the electrode pads 53, which is electrically connected to the power supply/ground layer 57, are provided, unnecessary electromagnetic radiation occurring from the transmission signal that flows through the mounting structure can be suppressed.

Moreover, the stiffness at the front surface side of the package substrate 51 can be enhanced without injecting an underfill resin between the semiconductor package 4 and the surface of the package substrate 51 because the conductive wires 31 exist over the surface of the package substrate 51. Therefore, the drop impact resistance of the mounting structure can be improved.

In addition, the package substrate 51 has a drawback that it is extremely thin and liable to be bent. However, in the mounting structure of the twelfth exemplary embodiment, it is advantageous in that warpage of the package substrate 51 can be reduced.

### Thirteenth Exemplary Embodiment

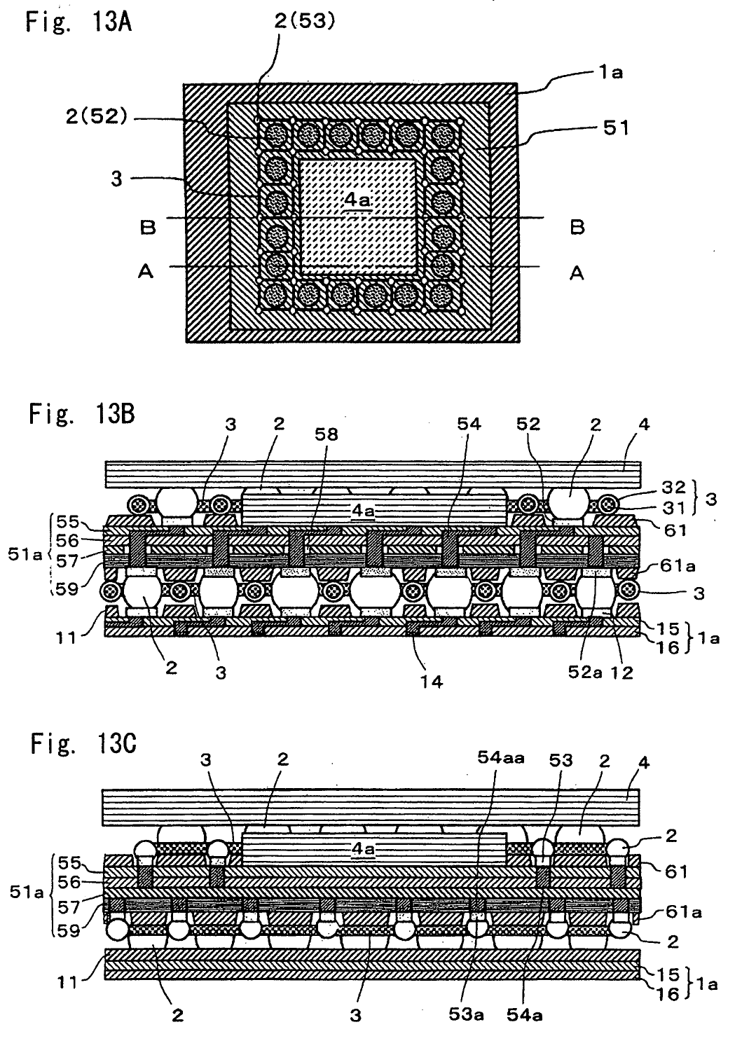

FIGS. 13A to 13C each show a mounting structure according to a thirteenth exemplary embodiment of the present invention. FIG. 13A is a perspective view from the top surface, showing an area between the semiconductor package 4a and a package substrate 51a constructing the mounting structure. FIGS. 13B and 13C are partial sectional views taken along the lines A-A and B-B of FIG. 13A, respectively.

The mounting structure of the thirteenth exemplary embodiment is equivalent to the following as shown in FIGS. 13A to 13C. That is, the package substrate 51a, which includes the insulating coating conductive wires 3 at both the front surface and back surface of the package substrate 51 and the semiconductor package 4a, is used in substitution for the package substrate 51, which includes the insulating coating conductive wires 3 only at the front surface of the package substrate and the semiconductor package 4a in the mounting structure of the twelfth exemplary embodiment. Therefore, the parts common to those of the above-described twelfth exemplary embodiment are denoted by the same reference numerals, and explanations thereof are omitted.

The plurality of circular electrode pads 52a, which are provided to be connected with the substrate 1a, and the plurality of circular electrode pads 53a, which are provided to mechanically and electrically connect the conductive wires 31 of the plurality of insulating coating conductive wires 3, are formed on the back surface of the package substrate 51a. The electrode pads 53a are smaller than the electrode pads 52a. The part except the electrode pad 52a and the electrode pad 53a formed in the back surface of the package substrate 51a is covered with the insulating solder-resist film 61a. Gaps are formed between the electrode pads 52a and the solder-resist film 61a and between the electrode pads 53a and the solder-resist film 61a.

In the inside of the package substrate 51a, the plurality of signal transmission lines 54 penetrating through the package substrate 51a (i.e., the insulating layer 55, the insulating layer 56, the power supply/ground layer 57, and the insulating layer 59) in the thickness direction thereof are formed. In addition, a plurality of power supply/ground lines 54aa penetrating through the insulating layer 59 are formed. Each back surface of the electrode pads 53a is mechanically and electrically connected to the lower end of the corresponding power supply/ground line 54aa. Each of the power supply/ground lines 54aa is electrically connected to the power supply/ground layer 57 in the package substrate 51a. Each of the electrode pads 53a has a size corresponding to the power supply /ground lines 54aa.

The electrode pads 52a on the back surface of the package substrate 51a are arranged in seven columns in the lengthwise direction (vertical direction in FIG. 13A) and in seven columns in the lateral direction (transverse direction in FIG. 13A) at substantially regular intervals. In other words, the electrode pads 52a form a matrix having seven columns in the lengthwise direction and seven columns in the lateral direction.

The electrode pads 53a on the back surface of the package substrate 51a are also arranged in eight columns in the lengthwise direction and in eight columns in the lateral direction at substantially regular intervals, like the electrode pads 52a. In other words, the electrode pads 52a form a matrix having eight columns in the lengthwise direction and eight columns in the lateral direction. The electrode pads 53a are arranged so as to surround each of the electrode pads 52a. When a square (a rectangle) around each of electrode pads 52a is assumed, the electrode pads 53a are arranged in the four corners of the square.

In addition, the plurality of insulating coating conductive wires 3 are placed below the back surface (on the solder-resist 61a) of the package substrate 51a. Each of the insulating coating conductive wires 3 is similar to that used in the above-mentioned first exemplary embodiment. The insulating coating conductive wires 3 are rectilinear and mechanically and electrically interconnect the electrode pads 53a aligning in the lengthwise direction or the lateral direction. The insulating coating conductive wires 3 are arranged in the shape of the matrix having seven columns in the lengthwise direction and seven columns in the lateral direction. Each of the electrode pads 52a is surrounded by a part of the four insulating coating conductive wires 3 placed between the two adjacent electrode pads 53a. In other words, the electrode pads 52a are separated by the insulating coating conductive wires 3. As regarding the electrode pads 53a, each of the electrode pads 53a is arranged at each intersection of the insulating coating conductive wires 3.

Like the first exemplary embodiment, each of the intersections (i.e., parts with the electrode pads 53a) of the insulating coating conductive wires 3 is provided with the ball-shaped solders 2. At each intersection of the insulating coating conductive wires 3, the insulating coatings 32 are peeled off, and the conductive wires 31 that are placed inside the insulating coatings 32 are exposed. Therefore, the two insulating coating conductive wires 3 intersecting at each intersection are mechanically and electrically connected, and mechanically and electrically connected to the corresponding electrode pads 53a. Each of the electrode pads 53a is mechanically and electrically connected to the power supply/ground layer 57 in the package substrate 51a through the corresponding power supply/ground line 54aa. Therefore, all the insulating coating conductive wires 3 are electrically connected to the power supply/ground layer 57.

Like the first exemplary embodiment, at each intersection of the insulating coating conductive wires 3, the conductive wires 31 are planarized beforehand. Therefore, the height at each intersection where two insulating coating conductive wires 3 overlap each other is not greater than that of the part except the intersection of the insulating coating conductive wires 3. Moreover, the intersecting insulating coating conductive wires 3 are interconnected in a stable state. In a plane view, the shape of the intersection is a cross-shape, an L-shape, or a T-shape, like the first exemplary embodiment.

In the mounting structure of the thirteenth exemplary embodiment, as mentioned earlier, all the conductive wires 31 of the insulating coating conductive wires 3 arranged in the surface of package substrate 51a are electrically connected to the power supply/ground layer 57 through the electrode pad 53 and the power supply/ground line 54a. In addition, all the conductive wires 31 of the insulating coating conductive wires 3 arranged in the back surface of the package substrate 51a are electrically connected to the same power supply/ground layer 57 through the electrode pad 53a and power supply/ground line 54aa. Thus, the effect that unnecessary electromagnetic radiation occurring inside the mounting structure is further inhibited compared with the mounting structure of the twelfth exemplary embodiment is provided.

Moreover, the conductive wires 31 of all the insulating coating conductive wires 3 arranged in the surface of the package substrate 51a are mechanically and electrically connected to the electrode pads 53 on the surface of package substrate 51a. In addition, the conductive wires 31 of all the insulating coating conductive wires 3 arranged in the back surface of the package substrate 51a are mechanically and electrically connected to the electrode pad 53a on the back surface of the package substrate 51a. Accordingly, the overall stiffness of the mounting structure becomes higher than that of the mounting structure of the twelfth exemplary embodiment. Therefore, the effect that the drop impact resistance of the mounting structure is further improved compared with the mounting structure of the twelfth exemplary embodiment is also provided without injecting an underfill resin between the semiconductor package 4 and the surface of the package substrate 51a.

There is another advantage that warpage of the package substrate 51a, which is extremely thin and liable to be bent, is further reduced.

### Fourteenth Exemplary Embodiment

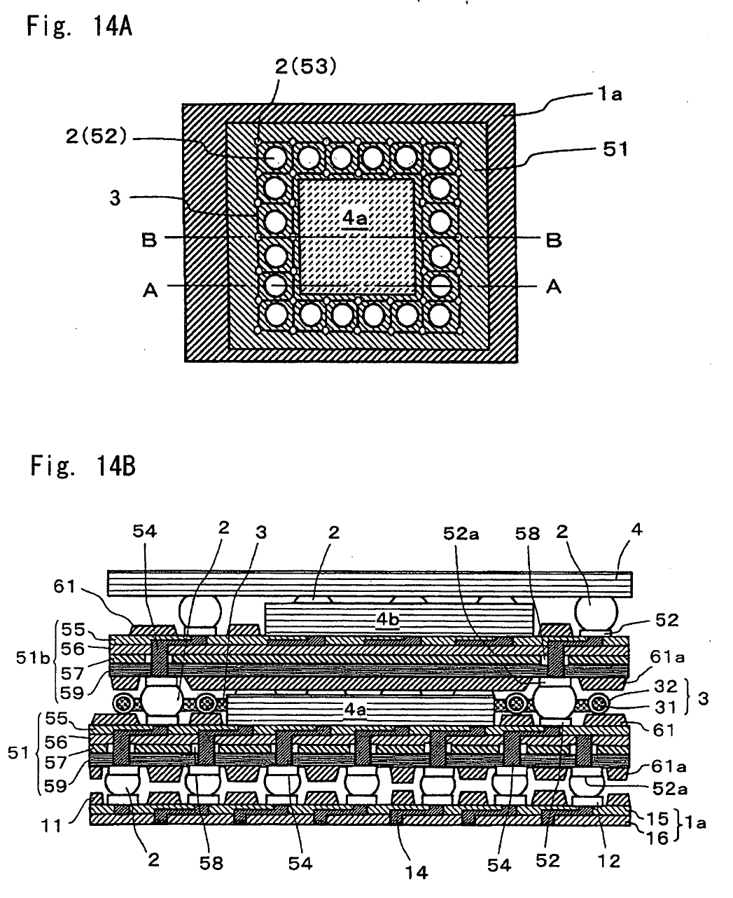

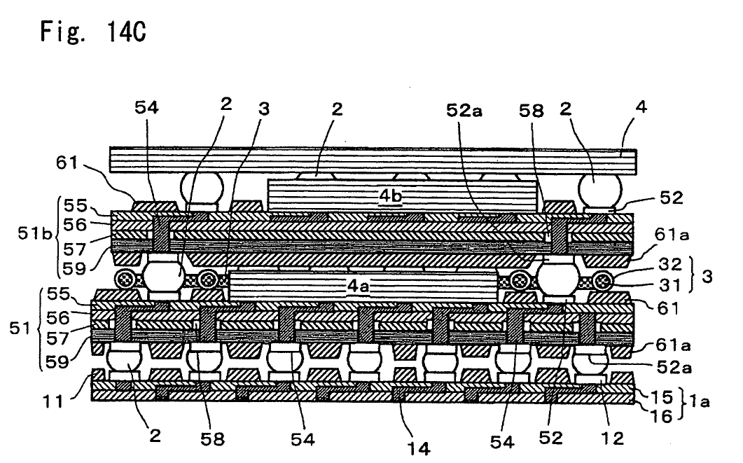

FIGS. 14A to 14C each show a mounting structure according to a fourteenth exemplary embodiment of the present invention. FIG. 14A is a perspective view from the top surface, showing an area between semiconductor package 4a and package substrate 51 constructing the mounting structure. FIGS. 14B and 14C are partial sectional views taken along the lines A-A and B-B of FIG. 14A, respectively.

The mounting structure of the fourteenth exemplary embodiment is equivalent to the following as shown in FIGS. 14A to 14C. That is, in the mounting structure of the twelfth exemplary embodiment, a package substrate 51b including a semiconductor package 4b is added between the semiconductor package 4 and the package substrate 51. Therefore, the parts common to those of the above-described twelfth exemplary embodiment are denoted by the same reference numerals, and explanations thereof are omitted.

The constitution of the package substrate 51b is almost the same as that of the package substrate 51 used in the twelfth exemplary embodiment, except that the insulating coating conductive wires 3 is not provided.

The package substrate 51b is constituted by laminating the insulating layers 55 and 56, the power supply/ground layer 57 (this has a predetermined pattern), and the insulating layer 59 in this order. In the central part of the surface (i.e., the surface of the insulating layer 55) of the package substrate 51, the semiconductor package 4b is implemented.

The plurality of circular electrode pads 52, which are provided to mount the semiconductor package 4, are further formed on the surface of the package substrate 51b so as to surround the semiconductor package 4b. The electrode pads 53 to mechanically and electrically connect the conductive wires 31 of the plurality of insulating coating conductive wires 3 are not formed. The part except the electrode pads 52 and the semiconductor package 4b formed on the surface of the package substrate 51b is covered with the insulating solder-resist film 61. Gaps are formed between the electrode pads 52 and the solder-resist film 61, and between the semiconductor package 4b and the solder-resist film 61. Each of the electrode pads 52 has a size corresponding to a plurality of electrode pads (not shown) formed on the back surface of the semiconductor package 4 which is disposed in the uppermost layer of the mounting structure.

The back surface (i.e., the surface of the insulating layer 59) of the package substrate 51b is provided with the electrode pads 52a to be connected with the substrate 1a as described above. The part except the electrode pads 52a formed on the back surface of the package substrate 51 is covered with the insulating solder-resist film 61a. Gaps are formed between each of the electrode pads 52a and the solder-resist film 61a.

In the inside of the package substrate 51b, the plurality of signal transmission lines 54 penetrating through the package substrate 51b (i.e., the insulating layers 55 and 56, the power supply/ground layer 57, and the insulating layer 59) in the thickness direction thereof are formed. The upper end of the corresponding signal transmission line 54 is mechanically and electrically connected to each back surface of the electrode pad 52 and each of electrode pads (not shown) of the semiconductor package 4b. The signal transmission lines 54 are electrically connected to the corresponding electrode pads 52a on the back surface of the package substrate 51b. The inside of the package substrate 51b does not have the power supply/ground line 54a.

The electrode pads 52a in the back surface of the package substrate 51b are mechanically and electrically connected to the corresponding electrode pads 52 in the surface of package substrate 51.

The semiconductor package 4 is mechanically and electrically connected to the package substrate 51b using the electrode pads 52 in the surface of the package substrate 51b.

In the mounting structure of the fourteenth exemplary embodiment, as mentioned earlier, between the semiconductor package 4 and the substrate 1a, the package substrate 51 including semiconductor package 4a and the package substrate 51b including the semiconductor package 4b are laminated. Moreover, in the surface of the package substrate 51, the electrode pads 53 to be electrically connected to the power supply/ground layer 57 are provided with the conductive wires 31 of the plurality of insulating coating conductive wires 3 connected with at least two points. Thus, unnecessary electromagnetic radiation occurring from a transmission signal flowing through the mounting structure can be inhibited.

Moreover, the stiffness at the front surface side of the package substrate 51 can be enhanced without injecting an underfill resin between the package substrate 51 and the package substrate 51b because the conductive wires 31 exist above the surface of the package substrate 51. Therefore, the drop impact resistance of the mounting structure can be improved.

In addition, the package substrate 51 and the package substrate 51a have a drawback that they are extremely thin and liable to be bent. However, in the mounting structure of the fourteenth exemplary embodiment, it is advantageous in that warpage of the package substrate 51 and the package substrate 51a can be reduced.

### Other Exemplary Embodiments

The above-mentioned first to fourteenth exemplary embodiments show preferred examples of the present invention.

Thus, the present invention is not limited to these embodiments, and it goes without saying that various kinds of modifications are possible.

### MODE FOR THE INVENTION

Next, an example of the present invention is described below, and the present invention is described still more specifically.

### (Mounting Structure)

The semiconductor package 4 with a full grid type of BGA having a ball diameter of 0.24 mm, a ball pitch of 0.4 mm, a ball interval of 0.16 mm, and having 304 balls was used. The semiconductor package 4 is not limited to a BGA type, but a commonly used package form such as LGA and CSP, as well as a bare-chip form may be used Moreover, not only a full grid type but also a type having no electrode in the center of the package and a type having an electrode only in the outer periphery of the package may be used.

### (Insulating Coating Conductive Wires 3)

As described above, because the ball interval of BGA is 0.16 mm, the conductive wires 31 having a diameter of 0.1 mm which can be fit into this interval was used. A copper (Cu) line material was used for the conductive wires 31. The minute line material 31 that can be processed to have such a diameter as to fit within the ball interval can be used. Thus, line materials such as nickel (Ni), tin (Sn), and gold (Au) can be used for the conductive wires 31.

For the insulating coatings 32 of the conductive wires 31, a fluoric resin which is generally used for insulating coating of the conductive material line in electronic devices can be used. Here, polyimide was used. Any insulating material can be used as long as the minute conductive wire 31 can be achieved and the insulating material has a heat resistance to the reflow process, in the mounting structure of the present invention. Note only resin materials such as polyimide, but also insulating ceramic materials such as steatite and silicon nitride can be applied.

### (Substrate 1)

As the electrode pads 12 and the electrode pads 13 formed on the surface of the substrate 1, pads obtained by plating Ni and Au on the surface of Cu were used. The diameters of both the electrode pad 12 and electrode pad 13 were 0.2 mm. The interval between the electrode pads 12 and 13 of 0.2 mm was large enough to mount and connect the BGA and the Cu wire.

The signal transmission lines 14 are wired so as to go through the location of the clearances 18 of the power supply/ground layer 17. Moreover, the conductive wires 31 are provided in the surface of the substrate 1 at a location substantially immediately above the clearance 18.

### (Solder 2)

Solder material used for the solder 2 was a lead-free solder having a composition of Sn-3.0Ag-0.5Cu. This is generally frequently used for electric apparatuses.

### (Manufacturing Method)

First, to the electrode pads 12 and electrode pads 13 in the surface of the substrate 1, a solder paste was supplied by a printing method. The supply of the solder is not limited to a printing method, but a method using a jet dispenser may be used. Then, using a well-known loader, a plurality of Cu wires serving as the insulating coating conductive wires 3 were arranged in one direction so as to surround each of the electrode pads 12 to mount the semiconductor package 4 and to overlap the electrode pads 13 connected to the power supply/ground layer 17. Afterwards, the solders 2 were supplied by a printing method onto the arranged Cu wires, using the same loader, the plurality of Cu wires were arranged in the direction at right angles to the Cu wires arranged earlier. In this way, the Cu wires were arranged in the shape of a lattice.

Because each intersection of the Cu wires is planarized beforehand, the intersection does not rise and can be connected in a stable state. The cross-section of the Cu wires at an intersecting part is not limited to a circle but may be another shape such as a semicircle, a rectangle, a square, or an ellipse. The height of each intersection may be equal to or lower than the height (thickness) of the Cu wires. Note that, the Cu wires can be connected by laser welding, without being limited to the connection with the solder. Moreover, the Cu wires may be arranged on the substrate 1 after being formed in a reticular shape beforehand.

Subsequently, using a well-known loader, the semiconductor package 4 of the BGA type was mounted on the electrode pads 12 on which no Cu wire was arranged.

Thus, upon completion of arranging the Cu wires (the insulating coating conductive wires 3) and the semiconductor package 4 on the substrate 1, a solder reflow process is carried out. Subsequently, the semiconductor package 4 is implemented in the surface of the substrate 1 using the electrode pads 12. In this way, the mounting structure of the present invention is provided.

The present invention has been described above with reference to exemplary embodiments, but the present invention is not limited to the above-mentioned details. In the constitution and details of the present invention, various changes that those skilled in the art can understand within the scope of the invention can be made.

This application is based upon and claims the benefit of priority from Japanese patent application No. 2008-055640, filed on Mar. 5, 2008 and Japanese patent application No. 2008-208262, filed on Aug. 12, 2008, the disclosure of which is incorporated herein in its entirety by reference.

### INDUSTRIAL APPLICABILITY

The present invention relates to a mounting structure and a method of manufacturing the same and, more particularly, the present invention is applicable to a mounting structure that includes a substrate and a semiconductor package mounted thereon and achieves both suppression of unnecessary electromagnetic radiation and improvement of drop impact resistance, and to a method of manufacturing the same.

1. A mounting structure having a substrate and a semiconductor package mounted thereon, comprising;
a plurality of first electrode pads forming the surface of the substrate and being provided for mounting the semiconductor package above the surface of the substrate;
a plurality of second electrode pads forming the surface of the substrate and being electrically connected to a power supply layer or a ground layer in the substrate; and
a first conductive wire being mechanically and electrically connected to the second electrode pads with at least two points above the surface of the substrate;
wherein the semiconductor package is mechanically and electrically connected to the surface of the substrate by using the first electrode pads.

2. The mounting structure according to claim 1, wherein
the second electrode pads are arranged at a location to overlap clearances formed in the power supply layer or the ground layer.

3. (canceled)

4. The mounting structure according to claim 1, wherein
the first conductive wire is provided in a plural number, and
at least one of the first conductive wires is connected to the second electrode pads with at least two points above the surface of the substrate.

5. The mounting structure according to claim 1, wherein
the first conductive wire is provided in a plural number, and
at least two of the first conductive wires are arranged in a cross-shape or a lattice shape above the surface of the substrate.

6. The mounting structure according to claim 1, wherein
the substrate comprises a package substrate comprising a semiconductor package.

7. The mounting structure according to claim 6, wherein
a plurality of third electrode pads, which are electrically connected to the power supply layer or the ground layer in the substrate;
and a second conductive wire, which is mechanically and electrically connected to the third electrode pads with at least two points, the third electrode pads and the second conductive wire being formed on the back surface of the substrate.

8. (canceled)

9. A manufacturing method of a mounting structure having a substrate and a semiconductor package mounted thereon, comprising;
preparing for a substrate having, formed on the surface thereof, a plurality of first electrode pads to mount a semiconductor package and a plurality of second electrode pads electrically connected in a power supply layer or a ground layer;
arranging, above the surface of the substrate, a first conductive wire mechanically and electrically connected to the second electrode pads with at least two points; and
mounting a semiconductor package above the surface of the substrate by employing the first electrode pads.

10. The manufacturing method of a mounting structure according to claim 9, wherein
the first conductive wire is provided in a plural number, and
a part of the first conductive wire is arranged in a first direction above the surface of the substrate, and then the remainder of the first conductive wire is arranged to be aligned in a second direction above the surface of the substrate, the second direction being different from the first direction.

11. The manufacturing method of a mounting structure according to claim 9, wherein
the first conductive wire is provided in a plural number,
a part of the first conductive wire is aligned in a first direction above the surface of the substrate, and then the remainder of the first conductive wire is aligned in a second direction above the surface of the substrate, the second direction being different from the first direction, and
all the first conductive wires are collectively arranged in the surface of the substrate.

12. The manufacturing method of a mounting structure according to claim 9, wherein
in the arranging the first conductive wire above the surface of the substrate, the first conductive wire is mechanically and electrically connected to the second electrode pad using a solder.

13. The mounting structure according to claim 2, wherein
the first conductive wire is provided in a plural number, and at least one of the first conductive wires is connected to the second electrode pads with at least two points above the surface of the substrate.

14. The mounting structure according to claim 2, wherein
the first conductive wire is provided in a plural number, and
at least two of the first conductive wires are arranged in a cross-shape or a lattice shape above the surface of the substrate.

15. The mounting structure according to claim 2, wherein
the substrate comprises a package substrate comprising a semiconductor package.

16. The mounting structure according to claim 16, wherein
a plurality of third electrode pads, which are electrically connected to the power supply layer or the ground layer in the substrate; and a second conductive wire, which is mechanically and electrically connected to the third electrode pads with at least two points, the third electrode pads and the second conductive wire being formed on the back surface of the substrate.
